(19) United States
(12) Patent Application Publication
(10) Pub. No.: US 2024/0313765 A1
(43) Pub. Date: Sep. 19, 2024

(54) BACKUP POWER SUPPLY SYSTEM, MOBILE OBJECT, AND BACKUP POWER SUPPLY SYSTEM CONTROLLING METHOD, AND PROGRAM

(71) Applicant: Panasonic Intellectual Property Management Co., Ltd., Osaka (JP)

(72) Inventors: HIROKI AKASHI, Osaka (JP); YOHSUKE MITANI, Osaka (JP); YUTA NAGATOMI, Osaka (JP); MASAFUMI NAKAMURA, Mie (JP); MASATOSHI NAKASE, Mie (JP); KINYA KATO, Shiga (JP); YASUHIRO IIJIMA, Osaka (JP)

(21) Appl. No.: 18/571,215

(22) PCT Filed: Jun. 23, 2022
(86) PCT No.: PCT/JP2022/025015

§ 371 Date: Dec. 16, 2023

(30) Foreign Application Priority Data
Jun. 29, 2021 (JP) 2021-108043
Nov. 25, 2021 (JP) 2021-191561

(51) Int. Cl. H03K 17/30; H03K 17/06; H03K 17/081

(52) U.S. Cl. CPC H03K 17/302; H03K 17/063; H03K 17/08104; H03K 2217/0081

(57) ABSTRACT

In a backup power supply system according to the present invention, in a non-defective state in which a main power supply is not defective, a controller turns on a first field-effect transistor and causes a third field-effect transistor to operate in an active region so as to charge the power storage device from the main power supply via a charging path through the first field-effect transistor, the second field-effect transistor, and the third field-effect transistor. In a defective state in which the main power supply is defective, the controller turns off the first field-effect transistor and turns on the second field-effect transistor and the third field-effect transistor so as to supply power from the power storage device to the load.

### TECHNICAL FIELD

The present disclosure relates to a backup power supply system, a movable object, a method for controlling the backup power supply system, and a program. More specifically, the present disclosure relates to a backup power supply system, a movable object, a method for controlling the backup power supply system, and a program for supplying power to a load when a main power supply is defective.

### BACKGROUND ART

PTL 1 discloses a power supply backup unit of a main power supply. The power supply backup unit described in PTL 1 includes a charging path through which an auxiliary power supply is charged from the main power supply via a diode, a P-channel FET constituting a current control switch, and a P-channel FET constituting a charging control circuit. In a case where power is supplied from the auxiliary power supply to an electronic controller that is a load, power is supplied from the auxiliary power supply to the electronic controller via a backup path through a diode connected in parallel to the P-channel FET constituting the charging control circuit and the P-channel FET constituting the current control switch.

### CITATION LIST

### Patent Literature

PTL 1: Japanese Patent Laid-Open Publication No. 2006-60950

### SUMMARY OF THE INVENTION

In the power supply backup unit having the above-described configuration, the diode is inserted in the charging path, and therefore, a voltage charged to the auxiliary power supply is a voltage lower than an output voltage of the main power supply by a forward voltage of the diode. The diode is inserted also in the backup path, and therefore, the voltage supplied to the electronic controller is lower than the voltage charged to the auxiliary power supply unit by a forward voltage of the diode. Accordingly, the voltage supplied from the auxiliary power supply to the electronic controller is a voltage that is lower than the output voltage of the main power supply by the forward voltages of two diodes. This configuration provides a problem that the voltage supplied to the electronic controller (load) decreases in a case where supply of backup power is performed.

An object of the present disclosure is to provide a backup power supply system, a movable object, a method for controlling the backup power supply system, and a program for preventing a decrease in a voltage supplied to a load in a case where the supply of backup power is performed.

A backup power supply system according to an aspect of the present disclosure includes a first connection terminal, a second connection terminal, a first field-effect transistor, a series circuit of a second field-effect transistor and a third field-effect transistor, and a controller. A main power supply is configured to be connected to the first connection terminal. A load is configured to be connected to the second connection terminal. The first field-effect transistor is connected between the first connection terminal and the second connection terminal. The series circuit of the second field-effect transistor and the third field-effect transistor is connected between a power storage device and a connection point of the first field-effect transistor and the second connection terminal. A body diode included in the second field-effect transistor is connected in a direction allowing a current to flow from the connection point to the power storage device. A body diode included in the third field-effect transistor is connected in a direction allowing a current to flow from the power storage device to the connection point. In a non-defective state in which the main power supply is not defective, the controller is configured to turn on the first field-effect transistor and cause the third field-effect transistor to operate in an active region so as to control a charging current flowing to the power storage device, thereby charging the power storage device from the main power supply through a charging path through the first field-effect transistor, the second field-effect transistor, and the third field-effect transistor. In a defective state in which the main power supply is defective, the controller is configured to turn off the first field-effect transistor and turn on the second field-effect transistor and the third field-effect transistor, thereby supplying power from the power storage device to the load.

A movable object according to an aspect of the present disclosure includes the backup power supply system and a main movable body. The backup power supply system, the main power supply, and the load are mounted on the main movable body.

A method for controlling a backup power supply system according to an aspect of the present disclosure includes a charging step and a backup feeding step. The backup power supply system includes a first connection terminal, a second connection terminal, a first field-effect transistor, and a series circuit of a second field-effect transistor and a third field-effect transistor. A main power supply is connected to the first connection terminal. A load is connected to the second connection terminal. The first field-effect transistor is connected between the first connection terminal and the second connection terminal. The series circuit of the second field-effect transistor and the third field-effect transistor is connected between a power storage device and a connection point of the first field-effect transistor and the second connection terminal. A body diode included in the second field-effect transistor is connected in a direction allowing a current to flow from the connection point to the power storage device. A body diode included in the third field-effect transistor is connected in a direction allowing a current to flow from the power storage device to the connection point. In the charging step, in a non-defective state in which the main power supply is not defective, the first field-effect transistor is turned on, and the third field-effect transistor operates in an active region so as to control a charging current flowing to the power storage device, thereby charging the power storage device from the main power supply via a charging path through the first field-effect transistor, the second field-effect transistor, and the third field-effect transistor. In the backup feeding step, in a defective state in which the main power supply is defective, the first field-effect transistor is turned off, and the second field-effect transistor and the third field-effect transistor are turned on, thereby supplying power from the power storage device to the load.

A program according to an aspect of the present disclosure is a program for causing a computer system to execute the method for controlling the backup power supply system.

The present disclosure provides a backup power supply system, a movable object, a method for controlling the backup power supply system, and a program preventing a decrease in a voltage supplied to a load in a case where the supply of backup power is performed.

### BRIEF DESCRIPTION OF DRAWINGS

FIG. 1 is a schematic circuit diagram of a backup power supply system according to Exemplary Embodiment 1 of the present disclosure.

FIG. 2 is a schematic circuit diagram of the backup power supply system.

FIG. 3 is a schematic circuit diagram of a driver circuit of the backup power supply system.

FIG. 4 is a waveform diagram showing an operation of the backup power supply system.

FIG. 5 is a waveform diagram showing an operation of the backup power supply system.

FIG. 6 is a waveform diagram showing an operation of the backup power supply system.

FIG. 7 is a waveform diagram showing an operation of the backup power supply system.

FIG. 8 is a waveform diagram showing an operation of the backup power supply system.

FIG. 9 is a waveform diagram showing an operation of the backup power supply system.

FIG. 10 is a schematic illustration view of a movable object including the backup power supply system.

FIG. 11 is a schematic circuit diagram of a backup power supply system according to Exemplary Embodiment 2 of the present disclosure.

FIG. 12 is a schematic circuit diagram of the backup power supply system.

FIG. 13 is a waveform diagram showing an operation of the backup power supply system.

FIG. 14 is a schematic circuit diagram of a backup power supply system according to Modification 1 of the present disclosure.

FIG. 15 is a waveform diagram showing an operation of the backup power supply system.

FIG. 16 is a waveform diagram showing an operation of the backup power supply system.

FIG. 17 is a schematic circuit diagram of a backup power supply system according to Modification 2 of the present disclosure.

FIG. 18 is a waveform diagram showing an operation of the backup power supply system.

FIG. 19 is a schematic circuit diagram of a backup power supply system according to Modification 3 of the present disclosure.

FIG. 20 is a schematic circuit diagram of the backup power supply system.

FIG. 21 is a flowchart showing an operation of the backup power supply system.

FIG. 22 is a flowchart showing another operation of the backup power supply system.

FIG. 23 is a schematic circuit diagram of a backup power supply system according to Modification 4 of the present disclosure.

### DESCRIPTION OF EMBODIMENTS

Hereinafter, an embodiment of a backup power supply system will be described. Each drawing described in the following embodiments is a schematic drawing, and a ratio of a size to a thickness of each component in each drawing does not necessarily reflect an actual dimension ratio.

### Overview

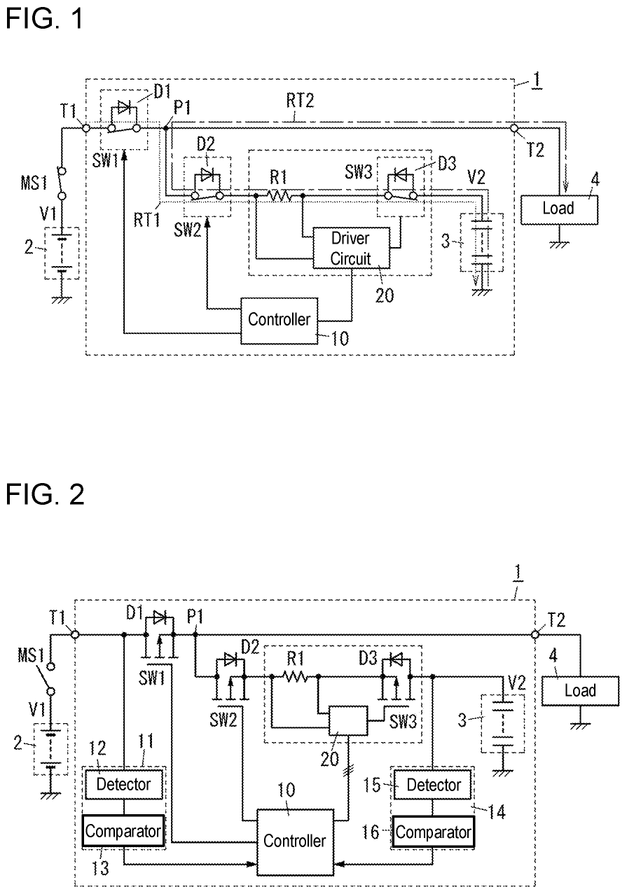

As shown in FIG. 1, backup power supply system 1 according to the present embodiment includes first connection terminal T1, second connection terminal T2, first field-effect transistor SW1, second field-effect transistor SW2, third field-effect transistor SW3, and controller 10.

Main power supply 2 is configured to be connected to first connection terminal T1. Load 4 is configured to be connected to second connection terminal T2. First field-effect transistor SW1 is connected between first connection terminal T1 and second connection terminal T2. A series circuit of second field-effect transistor SW2 and third field-effect transistor SW3 connected in series to each other is connected between power storage device 3 and connection point P1 of first field-effect transistor SW1 and second connection terminal T2. Body diode D2 included in second field-effect transistor SW2 is connected in a direction allowing a current to flow from connection point P1 to power storage device 3 Body diode D3 included in third field-effect transistor SW3 is connected in a direction allowing a current to flow from power storage device 3 to connection point P1.

In a non-defective state in which main power supply 2 is not defective, controller 10 is configured to turn on first field-effect transistor SW1 and cause third field-effect transistor SW3 to operate in an active region to control a charging current flowing to power storage device 3, thereby charging power storage device 3 via charging path RT1. Charging path RT1 is a path through which a current flows from main power supply 2 to power storage device 3 through first field-effect transistor SW1, second field-effect transistor SW2, and third field-effect transistor SW3. In a defective state in which main power supply 2 is defective, controller 10 is configured to turn off first field-effect transistor SW1 and turn on second field-effect transistor SW2 and the third field-effect transistor SW3, thereby supplying power from power storage device 3 to load 4. In the defective state, a path through which a discharging current from power storage device 3 flows to load 4 may include backup path RT2. Backup path RT2 is a path through which a current flows from power storage device 3 to load 4 through third field-effect transistor SW3 and second field-effect transistor SW2.

In the non-defective state, power is supplied from main power supply 2 to load 4 via first field-effect transistor SW1, and a charging current flows from main power supply 2 to power storage device 3 to charge power storage device 3. Backup power supply system 1 according to the embodiment is used to supply power from power storage device 3 to load 4 in the defective state.

The defective state in which main power supply 2 is defective is a state in which the supply of power from main power supply 2 to load 4 is stopped due to a defective, deterioration, disconnection, or the like of main power supply 2. The non-defective state in which main power supply 2 is not defective is a state in which power is supplied from main power supply 2 to load 4, and load 4 is operable with the power supplied from main power supply 2. Controller 10 turning on first to third field-effect transistors SW1 to SW3 means that controller 10 causes first to third field-effect transistors SW1 to SW3 to operate in a saturation region. Controller 10 turning off the first to third field-effect transistors SW1 to SW3 means that controller 10 causes first to third field-effect transistors SW1 to SW3 to operate in a cutoff region. Even in a state that first to third field-effect transistors SW1 to SW3 are controlled to operate in the cutoff region, a forward current can flow through body diodes D1 to D3 since first to third field-effect transistors SW1 to SW3 include body diodes D1 to D3.

Controller 10 causes third field-effect transistor SW3 to operate in the active region so as to control the charging current flowing to power storage device 3. For example, controller 10 performs a current control until a charging voltage of power storage device 3 reaches a predetermined target value (target voltage value). For example, after the charging voltage of power storage device 3 reaches the target value, controller 10 performs a constant voltage control preventing the voltage from not decreasing by discharging due to an internal resistance in a cell, and performs control (for example, a trickle charging) of maintaining the charging voltage constant. In order to perform the current control and the constant voltage control, controller 10 causes third field-effect transistor SW3 to operate in a saturation region or an active region (linear region), and controls a magnitude of the current flowing through third field-effect transistor SW3.

As described above, in backup power supply system 1 according to the present embodiment, second field-effect transistor SW2 and third field-effect transistor SW3 are shared by charging path RT1 and backup path RT2. This configuration reduces the number of field-effect transistors, thus providing an advantageous effect reducing a mounting space of a circuit board where the field-effect transistor is mounted and reducing the size of the circuit board accordingly.

Charging path RT1 is a path through which a current flows from main power supply 2 to power storage device 3 through first field-effect transistor SW1, second field-effect transistor SW2, and third field-effect transistor SW3. When first field-effect transistor SW1 and second field-effect transistor SW2 are turned on, a voltage drop due to a forward voltage of the diode is not produced. Controller 10 causes third field-effect transistor SW3 to operate in the active region. An on-resistance of third field-effect transistor SW3 is small, and the voltage drop generated in third field-effect transistor SW3 is smaller than a forward voltage of a diode. Therefore, in a case where power storage device 3 is charged via charging path RT1, a voltage drop due to the forward voltage of the diode is not produced, and therefore, a decrease in the charging voltage of power storage device 3 is prevented.

Backup path RT2 is a path through which a current flows from power storage device 3 to load 4 through third field-effect transistor SW3 and second field-effect transistor SW2. When third field-effect transistor SW3 and second field-effect transistor SW2 are turned on, a voltage drop due to a forward voltage of a diode is not produced, and therefore, a decrease in the voltage drop of load 4 is prevented.

As described above, a voltage drop due to a forward voltage of a diode is not produced in charging path RT1 and backup path RT2, hence providing an advantageous effect that a decrease in the voltage supplied to load 4 in a case where supply of backup power is performed is prevented.

Backup power supply system 1 is mounted on a movable object, such as vehicle 9 (see FIG. 10). That is, the movable object includes backup power supply system 1 and main movable body 91 (for example, a vehicle body of vehicle 9). Main movable body 91 includes backup power supply system 1, main power supply 2, and load 4. Backup power supply system 1 is configured to supply power from power storage device 3 to load 4 (for example, an electric brake system) in a case where main power supply 2 of vehicle 9 (for example, a battery of vehicle 9) is defective. Accordingly, load 4 continuously operates with the supply of power from power storage device 3 even in a case where main power supply 2 is defective.

FIG. 10 is a schematic diagram of vehicle 9 having backup power supply system 1 mounted thereon. In the vehicle body of vehicle 9, positions of backup power supply system 1, main power supply 2, and load 4 are not limited to positions shown in FIG. 10 and may be appropriately changed. In according to the embodiment, backup power supply system 1 is mounted on vehicle 9, but the movable object is not limited to vehicle 9 and may be an airplane, a ship, a train, or the like. Backup power supply system 1 is not limited to being mounted on the movable object, and may be disposed and used in a facility or the like.

### (1) Exemplary Embodiment 1

Hereinafter, backup power supply system 1 according to Embodiment 1 will be described in detail with reference to FIGS. 2 to 9.

### (1.1) Configuration

FIG. 2 is a specific circuit diagram of backup power supply system 1 described above (see FIG. 1). Backup power supply system 1 includes first connection terminal T1, second connection terminal T2, first to third field-effect transistors SW1 to SW3, controller 10, and power storage device 3. Backup power supply system 1 further includes current detection resistor R1, driver circuit 20, defective detection unit 11, and charging voltage detection unit 14.

Power storage device 3 is, for example, an electrical double layer capacitor (EDLC) rapidly chargeable and rapidly dischargeable. Power storage device 3 may include two or more power storage devices (for example, electrical double layer capacitors) electrically connected in parallel or in series to one another, or may include plural power storage devices (for example, electrical double layer capacitors) electrically connected in parallel and in series to one another. That is, power storage device 3 may be implemented by a parallel circuit or a series circuit of two or more power storage devices connected in parallel or series to one another, or a combination thereof.

Main power supply 2, such as a battery of vehicle 9, is configured to be connected to first connection terminal T1 via main switch MS1 included in vehicle 9. When main switch MS1 is turned on, power supply voltage V1 is input from main power supply 2 to first connection terminal T1 via main switch MS1.

Load 4 is configured to be connected to second connection terminal T2. Load 4 is, for example, an electric brake system mounted on vehicle 9. Load 4 is not limited to the electric brake system, and may be a device of a control system or a drive system related to advanced driver-assistance systems (ADAS).

First to third field-effect transistors SW1 to SW3 are, for example, P-channel metal-oxide-semiconductor field-effect transistors (MOSFETs).

The drain of first field-effect transistor SW1 is connected to first connection terminal T1, and the source of first field-effect transistor SW1 is connected to second connection terminal T2. Body diode D1 of first field-effect transistor SW1 is connected in a direction allowing a current to flow from first connection terminal T1 to second connection terminal T2.

The drain of second field-effect transistor SW2 is connected to connection point P1, and the source of second field-effect transistor SW2 is connected to the source of third field-effect transistor SW3 via current detection resistor R1. The drain of third field-effect transistor SW3 is connected to a positive terminal of power storage device 3. A negative terminal of power storage device 3 is connected to a reference potential of backup power supply system 1. Here, while second field-effect transistor SW2 is turned off, body diode D2 of second field-effect transistor SW2 prevents a current from flowing from power storage device 3 to connection point P1. While third field-effect transistor SW3 is turned off, body diode D3 of third field-effect transistor SW3 prevents a current from flowing from connection point P1 to power storage device 3.

Defective detection unit 11 includes detector 12 and comparator 13.

Detector 12 is configured to detect a voltage value of power supply voltage V1 input to first connection terminal T1.

Comparator 13 is configured to compare the voltage value of power supply voltage V1 detected by detector 12 with a threshold to detect whether main power supply 2 is in a defective state in which main power supply 2 is defective or in a non-defective state in which main power supply 2 is not defective. Comparator 13 outputs a detection result of the defective state or the non-defective state to controller 10.

The threshold is a lower limit value of a voltage range regarded as the non-defective state, and is set to, for example, a value lower than a rated voltage of main power supply 2. The threshold may include a first threshold for detecting the occurrence of the defective state and a second threshold for detecting restoration from the defective state to the non-defective state. The first threshold and the second threshold may be the same value or may be different values.

Charging voltage detection unit 14 includes detector 15 and comparator 16.

Detector 15 is configured to detect a voltage value of a connection point between third field-effect transistor SW3 and power storage device 3, that is, a voltage value of charging voltage V2 which is a voltage across of power storage device 3.

Comparator 16 is configured to compare the voltage value of charging voltage V2 detected by detector 15 with the target voltage value, and outputs a comparison result to controller 10.

Controller 10 is configured to control first to third field-effect transistors SW1 to SW3. Backup power supply system 1 includes driver circuit 20 configured to drive third field-effect transistor SW3, and includes controller 10 configured to control an operation of driver circuit 20 to control third field-effect transistor SW3.

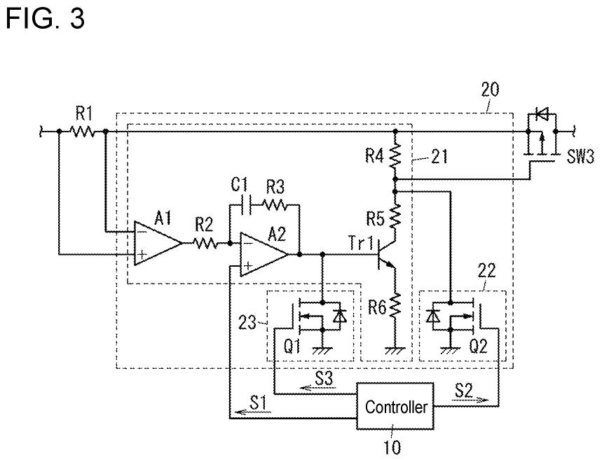

Driver circuit 20 includes first drive circuit 21, second drive circuit 22, and third drive circuit 23 as shown in FIG. 3.

First drive circuit 21 is configured to cause third field-effect transistor SW3 to operate in the active region based on current command value S1 input from controller 10 and a voltage across current detection resistor R1 connected between connection point P1 and power storage device 3.

First drive circuit 21 includes current detection amplifier A1, differential amplifier A2, resistors R2 to R6, and capacitor C1.

Current detection amplifier A1 is configured to amplify the voltage across current detection resistor R1 and output a voltage proportional to the magnitude of the current flowing through third field-effect transistor SW3.

Differential amplifier A2, resistors R2 and R3, and capacitor C1 constitute a differential amplifier circuit. The differential amplifier circuit outputs a voltage corresponding to a difference voltage between the output voltage of current detection amplifier A1 and current command value S1 input from controller 10. Current command value S1 is a voltage signal. A voltage value of current command value S1 is proportional to a target value of the current flowing through third field-effect transistor SW3. When the output voltage of current detection amplifier A1 is higher than current command value S1, the differential amplifier circuit decreases the output voltage of the differential amplifier circuit. When the output voltage of current detection amplifier A1 is lower than current command value S1, the differential amplifier circuit increases the output voltage of the differential amplifier circuit.

The output voltage of the differential amplifier circuit is input to the base of transistor Tr1. The emitter of transistor Tr1 is connected to the source of third field-effect transistor SW3 via resistors R5 and R4. The collector of transistor Tr1 is connected to the reference potential via resistor R6. A current flowing through transistor Tr1 depends on the magnitude of the output voltage of the differential amplifier circuit, and changes a voltage of the gate and source of third field-effect transistor SW3, thereby changing a-source resistance value between the drain and source of third field-effect transistor SW3 accordingly.

That is, first drive circuit 21 is configured to cause third field-effect transistor SW3 to operate in the active region (linear region) in response to current command value S1 input from controller 10 so that the current flowing through third field-effect transistor SW3 has a current value corresponding to current command value S1. Current command value S1 with a constant value performs a current control of maintaining the charging current to power storage device 3 at a constant value.

Second drive circuit 22 turns on third field-effect transistor SW3 based on On-signal S2 input from controller 10. Second drive circuit 22 includes field-effect transistor Q2 connected between the reference potential and a connection point of resistors R4 and R5. Field-effect transistor Q2 is turned on in response to On-signal S2 input from controller 10. When field-effect transistor Q2 is turned on, a voltage exceeding a pinch-off voltage is generated between the drain and source of third field-effect transistor SW3, causes third field-effect transistor SW3 to operate in the saturation region, that is, to be turned on.

Third drive circuit 23 turns off third field-effect transistor SW3 based on Off-signal S3 input from controller 10. Third drive circuit 23 includes field-effect transistor Q1 connected between the base of transistor Tr1 and the reference potential. Field-effect transistor Q1 is turned on in response to Off-signal S3 input from controller 10. When field-effect transistor Q1 is turned on while field-effect transistor Q2 is turned off, transistor Tr1 is turned off. Therefore, the voltage between the gate and source of third field-effect transistor SW3 becomes zero, and causes third field-effect transistor SW3 to operate in the cutoff region, that is, to be turned off.

### (1.2) Operation

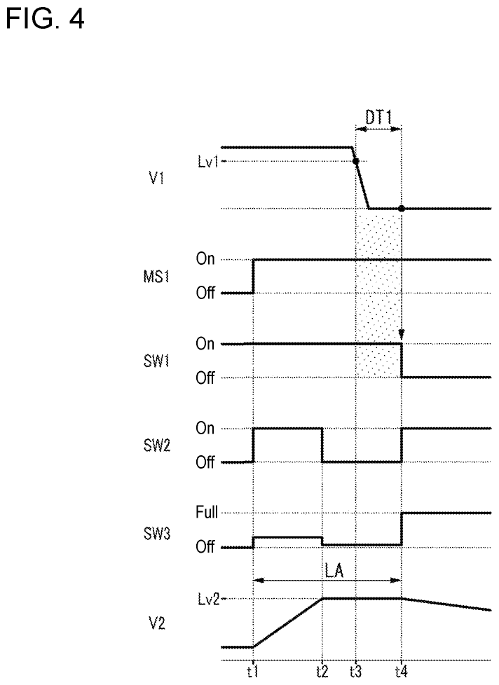

An operation of backup power supply system 1 according to Embodiment 1 will be described below with reference to FIGS. 4 to 9.

(1.2.1) Operation in Case Where Defective Occurs after Completing Charging

An operation of backup power supply system 1 in a case where main power supply 2 becomes defective after the charging of power storage device 3 is completed will be described below with reference to, e.g., FIG. 4.

When main switch MS1 is turned on at time point t1, power supply voltage V1 is supplied from main power supply 2 to backup power supply system 1. A voltage value of power supply voltage V1 exceeds threshold Lv1 for a period from time point t1 to time point t3, and therefore, defective detection unit 11 detects that main power supply 2 is in the non-defective state. Then, controller 10 turns on first and second field-effect transistors SW1 and SW2. In a first period from time point t1 to time point t2, a voltage value of charging voltage V2 of power storage device 3 is equal to or lower than target voltage value Lv2, and therefore, controller 10 causes, based on the detection result of charging voltage detection unit 14, third field-effect transistor SW3 to operate in the saturation region or the active region so as to cause the voltage value of charging voltage V2 of power storage device 3 to be target voltage value Lv2. That is, controller 10 causes third field-effect transistor SW3 to operate in the saturation region or the active region to perform a current control in the non-defective state in the first period until charging voltage V2 of power storage device 3 reaches target voltage value Lv2 so as to cause charging voltage V2 of power storage device 3 to become target voltage value Lv2. Accordingly, the charging current flows from main power supply 2 to power storage device 3 via charging path RT1, and gradually increases charging voltage V2 of power storage device 3.

When charging voltage V2 of power storage device 3 reaches target voltage value Lv2 at time point t2, controller 10 turns on first field-effect transistor SW1 and turns off second field-effect transistor SW2 based on the detection result of charging voltage detection unit 14. In a second period after time point t2 at which charging voltage V2 reaches target voltage value Lv2, controller 10 causes third field-effect transistor SW3 to operate in the active region so that the charging voltage is not decreased by the discharging due to the internal resistance of the cell of power storage device 3, and performs the constant voltage control to maintain charging voltage V2 at target voltage value Lv2. That is, controller 10 causes third field-effect transistor SW3 to operate in the active region to perform a voltage control in the non-defective state in the second period after the first period so that charging voltage V2 of power storage device 3 is maintained at target voltage value Lv2. Here, a current flowing through third field-effect transistor SW3 in the second period has a smaller value than that in the first period, and therefore, the resistance between the drain and source of third field-effect transistor SW3 is higher than that in the first period. Period LA in FIG. 4 indicates a period in which third field-effect transistor SW3 operates in the active region.

After that, when main power supply 2 becomes defective and causes power supply voltage V1 to be lower than threshold Lv1 at time point t3, defective detection unit 11 detects the defective state of main power supply 2 and outputs the detection result to controller 10. When the defective state occurs, controller 10 turns on first field-effect transistor SW1 and turns off second and third field-effect transistors SW2 and SW3. Second field-effect transistor SW2 which is turned off prevents a current from flowing from power storage device 3 to main power supply 2.

When the defective state continues for predetermined masking period DT1 from time point t3 at which the defective of main power supply 2 is detected, controller 10 turns off first field-effect transistor SW1 and turns on second and third field-effect transistors SW2 and SW3 at time point t4, thereby allowing power to be supplied from power storage device 3 to load 4 via backup path RT2. Then, load 4 operates with the power supplied from power storage device 3 even in a case where the defective state occurs.

Masking period DT1 is determined to be, for example, about several tens of pec to several hundreds of pec. For example, in a case where the detection of the defective state by defective detection unit 11 does not continue for masking period DT1 or longer even if dust or the like adheres to main power supply 2 and a short circuit occurs temporarily, the supply of backup power from power storage device 3 is not performed. Therefore, an erroneous operation of backup power supply system 1 is prevented.

In a case where backup power supply system 1 is used for vehicle 9, for example, while an ignition switch is turned off, controller 10 preferably turns on second and third field-effect transistors SW2 and SW3 to discharge the charging voltage of power storage device 3. Here, controller 10 may decrease the charging voltage of power storage device 3 to 0 V as long as the charging voltage of power storage device 3 is lower than the charging voltage when the ignition switch is turned on. In a case where the ignition switch is turned off, the vehicle 9 is stopped, and does not need to supply backup power to load 4. Therefore, power storage device 3 may be discharged to extend the life of power storage device 3.

(1.2.2) Operation in Case Where Defective Occurs for Time Shorter than Masking Period after Completing Charging

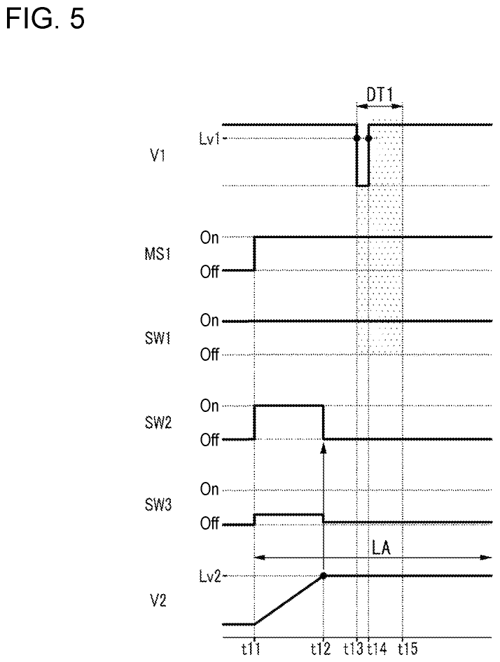

Next, an operation of backup power supply system 1 in a case where main power supply 2 is defective for a time shorter than masking period DT1 after the completion of the charging of power storage device 3 will be described below with reference to, e.g., FIG. 5.

An operation from time point t11 at which main switch MS1 is turned on to time point t13 at which the short time defective occurs is the same as the operation from time point t1 to time point t3 described in “(1.2.1) Operation in Case Where Defective Occurs after Completing Charging”, and therefore, description thereof will be omitted.

A voltage value of power supply voltage V1 becomes lower than the threshold Lv1 at time point t13, and defective detection unit 11 detects that the defective state occurs. Here, when the voltage value of power supply voltage V1 becomes equal to or higher than threshold Lv1 at time point t14 at which masking period DT1 elapses from time point t13, controller 10 determines, based on a detection result of defective detection unit 11, that the defective state is resolved. Then, controller 10 does not allow backup power to be supplied from power storage device 3, and causes first to third field-effect transistors SW1 to SW3 to operates in the same manner as those from time point t12 to time point t14. Period LA shown in FIG. 5 indicates a period in which third field-effect transistor SW3 operates in the active region.

(1.2.3) Operation in Case Where Defective Occurs after Completing Charging and then Main Power Supply is Restored

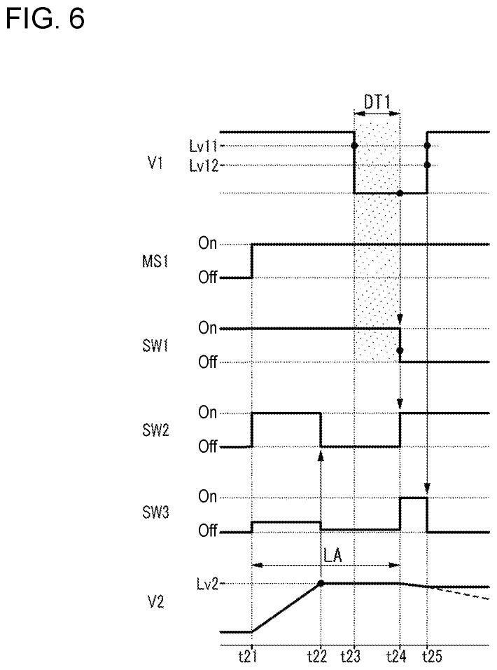

Next, an operation of backup power supply system 1 in a case where main power supply 2 is defective after completion of charging of power storage device 3, the supply of backup power is performed, and then main power supply 2 is restored will be described below with reference to, e.g., FIG. 6.

An operation from time point t21 at which main switch MS1 is turned on to time point t24 at which the supply of backup power is performed is the same as the operation from time point t1 to time point t4 described in “(1.2.1) Operation in Case Where Defective Occurs after Completing Charging”, and therefore, description thereof will be omitted. In the operation shown in FIG. 6, defective detection unit 11 detects the defective state when the voltage value of power supply voltage V1 is lower than first threshold Lv11, and detects the restoration (that is, the non-defective state) from the defective state when the voltage value of power supply voltage V1 is equal to or higher than second threshold Lv12.

At time point t24 at which the defective state continues for masking period DT1 from time point t23 at which the defective of main power supply 2 is detected, controller 10 turns off first field-effect transistor SW1 and turns on second and third field-effect transistors SW2 and SW3. Accordingly, power is supplied from power storage device 3 to load 4 via backup path RT2.

After that, when the defective state of main power supply 2 is resolved and power supply voltage V1 exceeds second threshold Lv12 at time point t25, controller 10 turns on second field-effect transistor SW2 and turns off third field-effect transistor SW3 based on a detection result of defective detection unit 11. When a defective of main power supply 2 occurs, controller 10 turns off first field-effect transistor SW1 even if the defective state of main power supply 2 is resolved after that.

When power supply voltage V1 is higher than charging voltage V2, power is supplied from main power supply 2 to load 4 via body diode D1 of first field-effect transistor SW1. On the other hand, when power supply voltage V1 is lower than charging voltage V2, power is supplied from power storage device 3 to load 4 via backup path RT2. Since third field-effect transistor SW3 is turned off, third field-effect transistor SW3 prevents a large current from flowing to power storage device 3 in a case where power supply voltage V1 of main power supply 2 is higher than charging voltage V2 of power storage device 3. First field-effect transistor SW1 which is turned off hardly allows a current to flow from power storage device 3 toward main power supply 2.

(1.2.4) Operation in Case Where Defective Occurs during Charging

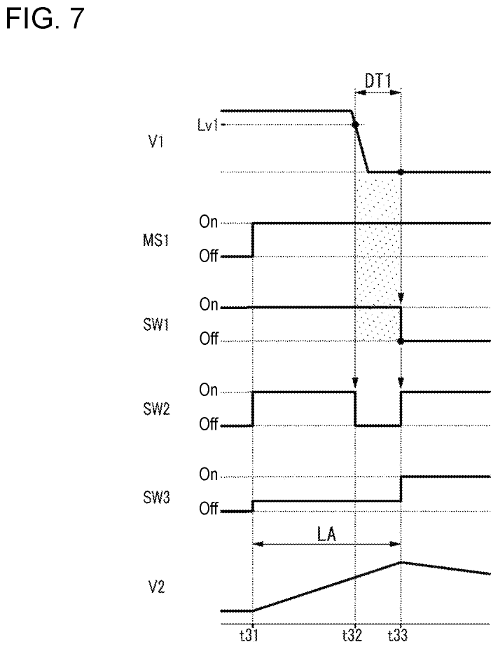

Next, an operation of backup power supply system 1 in a case where main power supply 2 is defective while charging of power storage device 3 will be described below with reference to, e.g., FIG. 7.

When main switch MS1 is turned on at time point t31, power supply voltage V1 is supplied from main power supply 2 to backup power supply system 1. Since a voltage value of power supply voltage V1 exceeds threshold Lv1 from time point t31 to time point t32, defective detection unit 11 detects that main power supply 2 is in the non-defective state. Then, controller 10 turns on first and second field-effect transistors SW1 and SW2. A voltage value of charging voltage V2 of power storage device 3 is equal to or lower than target voltage value Lv2 from time point t31 to time point t32, and therefore, controller 10 causes, based on a detection result of charging voltage detection unit 14, third field-effect transistor SW3 to operate in the active region so as to cause the voltage value of charging voltage V2 of power storage device 3 to be target voltage value Lv2. Accordingly, the charging current flows from main power supply 2 to power storage device 3 via charging path RT1, and gradually increases charging voltage V2 of power storage device 3.

When a defective of main power supply 2 occurs and power supply voltage V1 is lower than threshold Lv1 at time point t32, defective detection unit 11 detects the defective state of main power supply 2 and outputs a detection result to controller 10. When the defective state occurs, controller 10 turns on first field-effect transistor SW1 and turns off second field-effect transistor SW2. Then, second field-effect transistor SW2 which is turned off prevents a current from flowing from power storage device 3 toward main power supply 2.

When the defective state continues for masking period DT1 from time point t32 at which the defective of main power supply 2 is detected, at time point t33, controller 10 turns off first field-effect transistor SW1 and turns on second and third field-effect transistors SW2 and SW3. Accordingly, power is supplied from power storage device 3 to load 4 via backup path RT2. Therefore, load 4 operates with the power supplied from power storage device 3 even in a case where the defective state occurs.

### (1.2.5) Operation in Case Where Defective Occurs for Time Shorter Than Masking Period During Charging

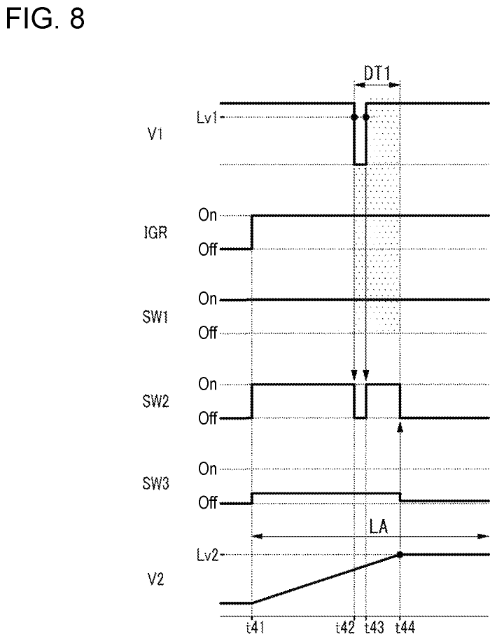

Next, an operation of backup power supply system 1 in a case where main power supply 2 is defective for a time shorter than masking period DTI during charging of power storage device 3 will be described below with reference to, e.g., FIG. 8.

An operation from time point t41 at which main switch MS1 is turned on to time point t42 at which the short-time short circuit occurs is the same as the operation from time point t31 to time point t32 described in “(1.2.4) Operation in Case Where Defective Occurs during Charging”, and therefore, description thereof will be omitted.

Since the voltage value of power supply voltage V1 is lower than threshold Lv1 at time point t42, defective detection unit 11 detects that the defective state occurs. Here, when the voltage value of power supply voltage V1 becomes equal to or higher than threshold Lv1 at time point t43 at which masking period DT1 elapses from time point t42, controller 10 determines, based on a detection result of defective detection unit 11, that the defective state is resolved. Then, controller 10 does not cause backup power to be supplied from power storage device 3, and causes first to third field-effect transistors SW1 to SW3 to operate in the same manner as those from time point t41 to time point t42 so as to continue the charging of power storage device 3.

After that, when charging voltage V2 of power storage device 3 reaches target voltage value Lv2 at time point t44, controller 10 turns on first field-effect transistor SW1 and turns off second field-effect transistor SW2 based on a detection result of charging voltage detection unit 14. In a second period after time point t44, controller 10 causes third field-effect transistor SW3 to operate in the active region and performs the trickle charging of power storage device 3 so as to maintain charging voltage V2 of power storage device 3 at target voltage value Lv2. Then, since a current flowing through third field-effect transistor SW3 has a smaller value than that in the first period, the resistance between the drain and source of third field-effect transistor SW3 is higher than that in the first period. Here, period LA shown in FIG. 8 indicates a period in which third field-effect transistor SW3 operates in the active region.

(1.2.6) Operation in Case Where Defective Occurs during Charging and then Main Power Supply is Restored

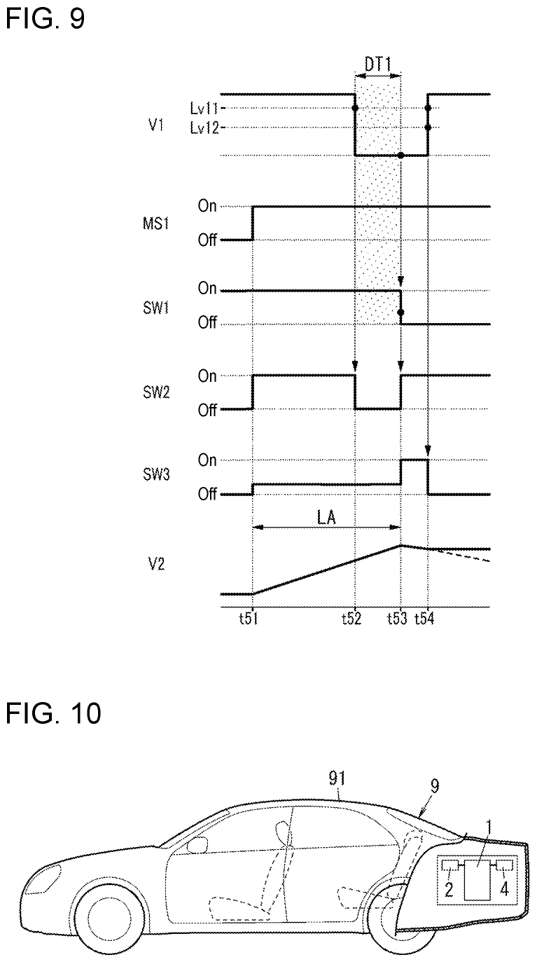

Next, an operation of backup power supply system 1 in a case where main power supply 2 is defective during charging of power storage device 3, the supply of backup power is performed, and then main power supply 2 is restored will be described below with reference to FIG. 9 and the like.

An operation from time point t51 at which main switch MS1 is turned on to time point t53 at which the supply of backup power is performed is the same as the operation from time point t31 to time point t33 described in “(1.2.4) Operation in Case Where Defective Occurs during Charging”, and therefore, description thereof will be omitted. In the operation example shown in FIG. 9, the defective detection unit 11 detects the defective state when the voltage value of power supply voltage V1 is lower than first threshold Lv11, and detects the restoration from the defective state when the voltage value of power supply voltage V1 is equal to or higher than second threshold Lv12.

At time point t53 at which the defective state continues for masking period DT1 from time point t52 at which the defective of main power supply 2 is detected, controller 10 turns off first field-effect transistor SW1 and turns on second and third field-effect transistors SW2 and SW3. Accordingly, power is supplied from power storage device 3 to load 4 via backup path RT2.

After that, when the defective state of main power supply 2 is resolved and power supply voltage V1 exceeds second threshold Lv12 at time point t54, controller 10 turns on second field-effect transistor SW2 and turns off third field-effect transistor SW3 based on a detection result of defective detection unit 11. When a defective of main power supply 2 occurs, controller 10 turns off first field-effect transistor SW1 even if the defective state of main power supply 2 is resolved after that.

When power supply voltage V1 is higher than charging voltage V2, power is supplied from main power supply 2 to load 4 via body diode D1 of first field-effect transistor SW1. On the other hand, when power supply voltage V1 is lower than charging voltage V2, power is supplied from power storage device 3 to load 4 via backup path RT2. Third field-effect transistor SW3 which is turned off prevents a large current from flowing to power storage device 3 in a case where power supply voltage V1 of main power supply 2 is higher than charging voltage V2 of power storage device 3. First field-effect transistor SW1 which is turned off hardly allow a current to flow from power storage device 3 toward main power supply 2.

In the above-described operations, backup power supply system 1 according to the present embodiment supplies of backup power from power storage device 3 to load 4 when main power supply 2 is defective.

### (2) Exemplary Embodiment 2

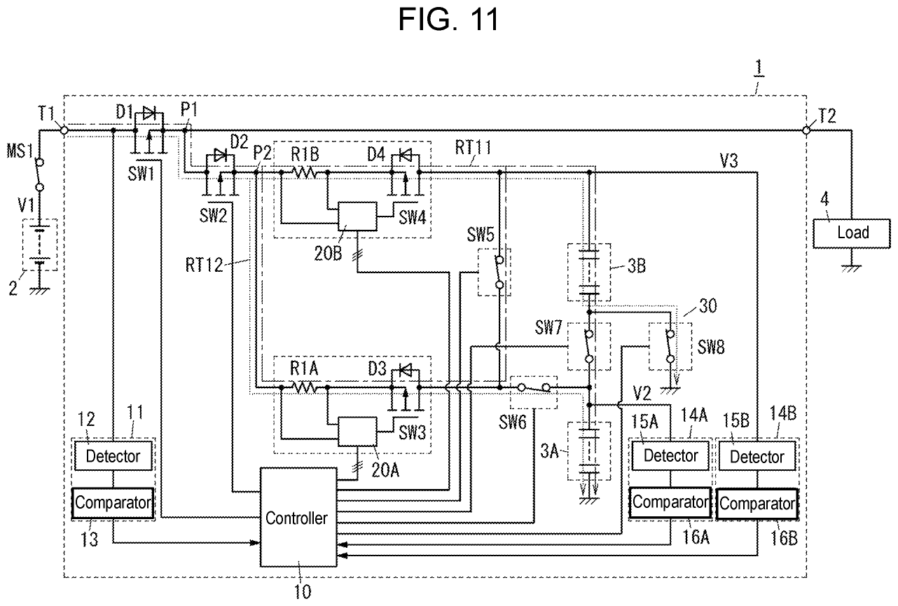

Backup power supply system 1 according to Exemplary Embodiment 2 will be detailed below with reference to FIGS. 11 to 13.

### (2.1) Configuration

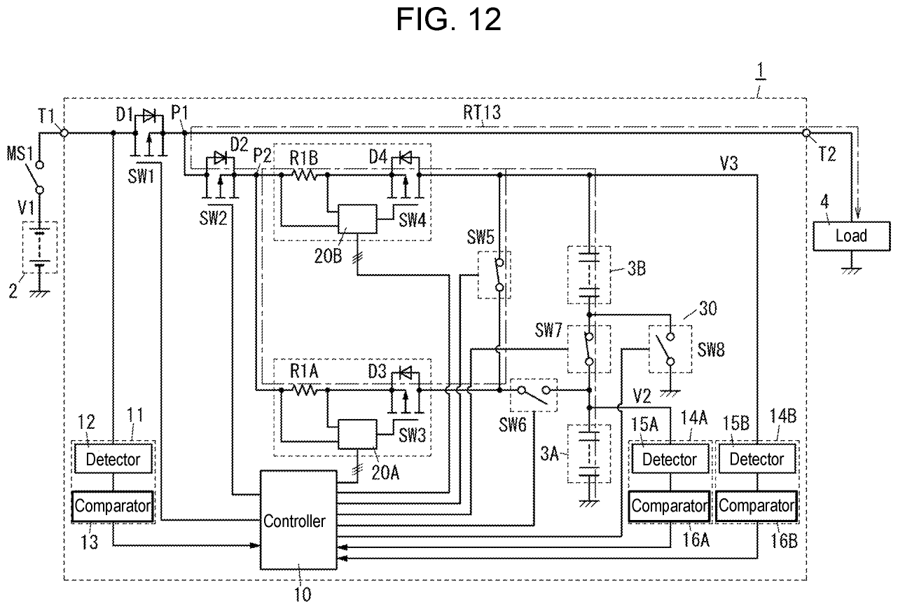

FIGS. 11 and 12 are schematic circuit diagrams of backup power supply system 1 according to Embodiment 2. Backup power supply system 1 according to Embodiment 2 further includes second power storage device 3B different from first power storage device 3A which is power storage device 3 described in Embodiment 1. Backup power supply system 1 further includes fourth field-effect transistor SW4 and switching circuit 30. Fourth field-effect transistor SW4 is connected between second power storage device 3B and a terminal (that is, a source) of second field-effect transistor SW2 proximal to third field-effect transistor SW3.

Current detection resistor R1A is connected between second field-effect transistor SW2 and third field-effect transistor SW3. Current detection resistor R1B is connected between second field-effect transistor SW2 and fourth field-effect transistor SW4. In other words, fourth field-effect transistor SW4 is connected to connection point P2 between second field-effect transistor SW2 and current detection resistor R1A via current detection resistor R1B.

Backup power supply system 1 further includes driver circuit 20A configured to drive third field-effect transistor SW3 and driver circuit 20B configured to drive fourth field-effect transistor SW4. In a case where second power storage device 3B is charged in the non-defective state, controller 10 causes fourth field-effect transistor SW4 to operate in the active region in order to control a charging current flowing to second power storage device 3B. In a case where power is supplied from second power storage device 3B to load 4 in the defective state, controller 10 turns on fourth field-effect transistor SW4. Driver circuits 20A and 20B have the same configuration and function as driver circuit 20 described in Embodiment 1, and therefore, description thereof will be omitted.

Backup power supply system 1 further includes first charging voltage detection unit 14A and second charging voltage detection unit 14B. First charging voltage detection unit 14A includes detector 15A and comparator 16A, and detects charging voltage V2 that is a voltage of a positive terminal of first power storage device 3A. Second charging voltage detection unit 14B includes detector 15B and comparator 16B, and detects charging voltage V3 that is a voltage of a positive terminal of second power storage device 3B. First charging voltage detection unit 14A and second charging voltage detection unit 14B have the same configuration and function as charging voltage detection unit 14 described in Embodiment 1, and therefore, description thereof will be omitted.

Switching circuit 30 is switched between a first state and a second state in response to a switching signal from controller 10. The first state is a state in which a series circuit of third field-effect transistor SW3 and first power storage device 3A connected in series to each other is connected in parallel to a series circuit of fourth field-effect transistor SW4 and second power storage device 3B connected in series to each other between second field-effect transistor SW2 and a reference potential. The second state is a state in which first power storage device 3A is connected in series to second power storage device 3B between second field-effect transistor SW2 and the reference potential via a parallel circuit of third field-effect transistor SW3 and fourth field-effect transistor SW4 connected in parallel to each other.

In the circuit according to the present embodiment, current detection resistor R1A is connected between connection point P2 and third field-effect transistor SW3, and current detection resistor R1B is connected between connection point P2 and fourth field-effect transistor SW4. Therefore, in the first state, a series circuit of current detection resistor R1A, third field-effect transistor SW3, and first power storage device 3A connected in series to one another is connected in parallel to a series circuit of current detection resistor R1B, fourth field-effect transistor SW4, and second power storage device 3B connected in series to one another between second field-effect transistor SW2 and the reference potential. In the second state, first power storage device 3A is connected in series to second power storage device 3B between second field-effect transistor SW2 and the reference potential via a parallel circuit in which a series circuit of current detection resistor R1A and third field-effect transistor SW3 connected in series to each other is connected in parallel to a series circuit of current detection resistor R1B and fourth field-effect transistor SW4 connected in series to each other.

Switching circuit 30 includes four switches SW5 to SW8. Switches SW5 to SW8 are implemented by, for example, MOSFETs. Switch SW5 is connected between the drain of third field-effect transistor SW3 and the drain of fourth field-effect transistor SW4. Switch SW6 is connected between the drain of third field-effect transistor SW3 and the positive terminal of first power storage device 3A. Switch SW7 is connected between the positive terminal of first power storage device 3A and a negative terminal of second power storage device 3B. Switch SW8 is connected between the negative terminal of second power storage device 3B and the reference potential. Switching circuit 30 provides the first state by turning off switches SW5 and SW7 and turning on switches SW6 and SW8 in response to a switching signal from controller 10. Switching circuit 30 provides the second state by turning on switches SW5 and SW7 and turning off switches SW6 and SW8 in response to a switching signal from controller 10.

### (2.2) Operation

An operation of backup power supply system 1 according to Embodiment 2 will be described with reference to FIGS. 11 to 13. An operation of backup power supply system 1 in a case where main power supply 2 is defective after the charging of first power storage device 3A and second power storage device 3B is completed will be described.

When main switch MS1 is turned on at time point t61, power supply voltage V1 is supplied from main power supply 2 to backup power supply system 1. The voltage value of power supply voltage V1 exceeds threshold Lv1 from time point t61 to time point t64, and therefore, defective detection unit 11 detects that main power supply 2 is in the non-defective state.

When power is supplied from main power supply 2 to controller 10 at time point t61, controller 10 turns on first and second field-effect transistors SW1 and SW2. Controller 10 turns on switches SW5 and SW7 and turns off switches SW6 and SW8 so as to switch switching circuit 30 to the second state. Controller 10 causes third and fourth field-effect transistors SW3 and SW4 to operate in the active region so as to control charging currents flowing to first power storage device 3A and second power storage device 3B. Then, the charging current flows from main power supply 2 to a series circuit of second power storage device 3B and first power storage device 3A through path RT11 passing through first field-effect transistor SW1, second field-effect transistor SW2, and a parallel circuit of third and fourth field-effect transistors SW3 and SW4 connected in parallel to each other. Accordingly, large charging currents flow to first power storage device 3A and second power storage device 3B, and shorten charging time of first power storage device 3A and second power storage device 3B. Third field-effect transistor SW3 and fourth field-effect transistor SW4 for controlling the charging current are connected in parallel to each other, thus reducing the impedance of the circuit and reducing the loss. In the second state, first power storage device 3A and second power storage device 3B are connected in series to each other, and therefore, charging voltage V3 detected by second charging voltage detection unit 14B is the sum of charging voltage V2 of first power storage device 3A and the charging voltage of second power storage device 3B.

When the voltage value of charging voltage V3 detected by second charging voltage detection unit 14B reaches predetermined switching voltage value Lv3 at time point t62, controller 10 turns off switches SW5 and SW7 and turns on switches SW6 and SW8 to switch switching circuit 30 to the first state.

That is, in a case where first power storage device 3A and second power storage device 3B are charged in the non-defective state, switching circuit 30 is switched to the first state in response to the switching signal. Then, a charging current flows from main power supply 2 to first power storage device 3A through first, second, and third field-effect transistors SW1, SW2, and SW3, and a charging current flows from main power supply 2 to second power storage device 3B through first, second, and fourth field-effect transistors SW1, SW2, and SW4. That is, the charging currents flow from main power supply 2 to first power storage device 3A and second power storage device 3B via path RT12 (see FIG. 11) so as to charge first power storage device 3A and second power storage device 3B to reach target voltage value Lv2. In a period (first period) from time point t61 to time point t63, controller 10 causes third and fourth field-effect transistors SW3 and SW4 to operate in the active region to perform a current control so that the charging voltage of power storage device 3 becomes predetermined target voltage value Lv2.

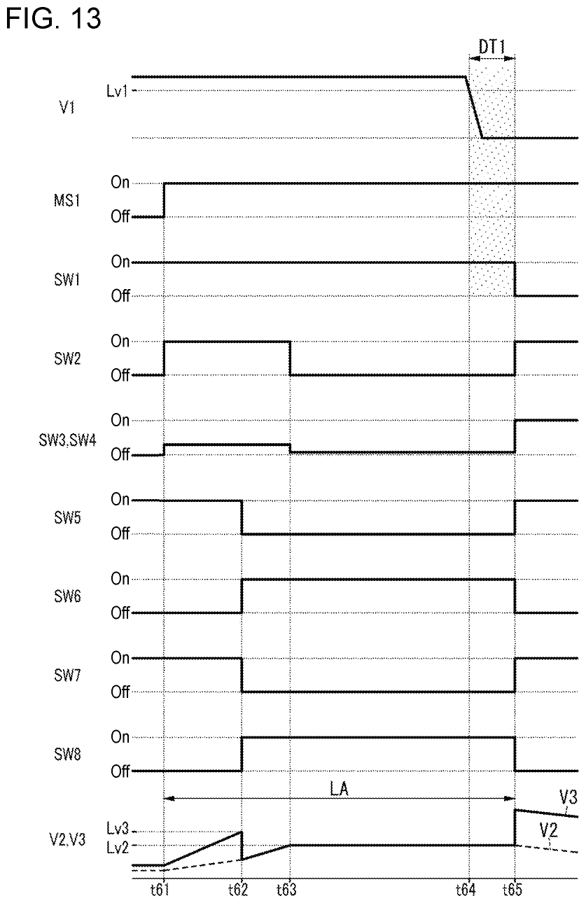

When charging voltages V2 and V3 of first power storage device 3A and second power storage device 3B reach target voltage value Lv2 at time point t63, controller 10 turns on first field-effect transistor SW1 and turns off second field-effect transistor SW2 based on detection results of first charging voltage detection unit 14A and second charging voltage detection unit 14B. In the second period after time point t63, controller 10 causes third and fourth field-effect transistors SW3 and SW4 to operate in the active region to perform a voltage control to maintain charging voltage V2 of first power storage device 3A and second power storage device 3B at target voltage value Lv2, and performs the trickle charge of power storage device 3. Then, a current flowing to third and fourth field-effect transistors SW3 and SW4 in the second period has a smaller value than that in the first period, and therefore, the resistance between the drain and source of each of third and fourth field-effect transistors SW3 and SW4 is higher than that in the first period. Here, period LA shown in FIG. 13 indicates a period in which third and fourth field-effect transistors SW3 and SW4 operate in the active region.

After that, when a defective of main power supply 2 occurs and power supply voltage V1 is lower than threshold Lv1 at time point t64, defective detection unit 11 detects the defective state of main power supply 2 and outputs a detection result to controller 10.

When the defective state continues for masking period DT1 from time point t64 at which the failure of main power supply 2 is detected, controller 10 turns off first field-effect transistor SW1 and turns on second and third field-effect transistors SW2 and SW3 at time point t65. Controller 10 turns on switches SW5 and SW7 and turns off switches SW6 and SW8 to switch switching circuit 30 to the second state. That is, in a case where power is supplied from first power storage device 3A and second power storage device 3B to load 4 in the defective state, switching circuit 30 is switched to the second state in response to the switching signal. Accordingly, power is supplied from first power storage device 3A and second power storage device 3B to load 4 via backup path RT13 (see FIG. 12) passing through second field-effect transistor SW2 and a parallel circuit of third field-effect transistor SW3 and fourth field-effect transistor SW4 connected in parallel to each other. Then, first power storage device 3A and second power storage device 3B are connected in series to each other, and therefore, a voltage higher than the charging voltage of each of first power storage device 3A and second power storage device 3B is supplied to load 4.

In according to the embodiment, in a case where first power storage device 3A and second power storage device 3B are charged in the non-defective state, controller 10 first outputs a switching signal to switch switching circuit 30 to the second state, and charges first power storage device 3A and second power storage device 3B in the second state (period t61 to t62). When the charging voltages of first power storage device 3A and second power storage device 3B connected in series to each other reach predetermined switching voltage value Lv3, controller 10 outputs a switching signal to switch switching circuit 30 to the first state, and charges first power storage device 3A and second power storage device 3B in the first state. As described above, first power storage device 3A and second power storage device 3B are first charged in the second state in which first power storage device 3A and second power storage device 3B are connected in series to each other, and therefore, first power storage device 3A and second power storage device 3B is rapidly charged. First power storage device 3A and second power storage device 3B are charged via the parallel circuit in which the series circuit of current detection resistor R1A and third field-effect transistor SW3 is connected in parallel to the series circuit of current detection resistor R1B and fourth field-effect transistor SW4, hence reducing the loss in the charging path. When the charging voltages of first power storage device 3A and second power storage device 3B connected in series to each other reach switching voltage value Lv3, first power storage device 3A and second power storage device 3B are separately charged in the first state. This configuration provides an advantageous effect that first power storage device 3A and second power storage device 3B is separately charged to reach target voltage value Lv2.

In the present embodiment, in a case where first power storage device 3A and second power storage device 3B are charged in the non-defective state, controller 10 may charge first power storage device 3A and second power storage device 3B in the first state without providing a period of the second state. That is, controller 10 may switch switching circuit 30 to the first state in a case where first power storage device 3A and second power storage device 3B are charged in the non-defective state, and switch switching circuit 30 to the second state during the supply of backup power.

The configuration (including the modification) described in Embodiment 2 is appropriately combined with the configuration (including the modification) described in Embodiment 1 and applied.

### (3) Modification

The above-described embodiment is merely one of various embodiments of the present disclosure. The above-described embodiment can be modified variously according to the design or the like as long as the object of the present disclosure can be achieved. The same functions as those of backup power supply system 1 may be implemented by a method for controlling backup power supply system 1, a computer program, a non-transitory recording medium in which the program is recorded, or the like. A method for controlling backup power supply system 1 according to an aspect includes a charging step and a backup feeding step. Backup power supply system 1 includes first connection terminal T1, second connection terminal T2, and first to third field-effect transistors SW1 to SW3. Main power supply 2 is configured to be connected to first connection terminal T1, and load 4 is configured to be connected to second connection terminal T2. First field-effect transistor SW1 is connected between first connection terminal T1 and second connection terminal T2. A series circuit of second field-effect transistor SW2 and third field-effect transistor SW3 connected in series to each other is connected between and power storage device 3 and connection point P1 of first field-effect transistor SW1 and second connection terminal T2. Body diode D2 included in second field-effect transistor SW2 is connected in a direction allowing a current to flow from connection point P1 to power storage device 3. Body diode D3 included in third field-effect transistor SW3 is connected in a direction allowing a current to flow from power storage device 3 to connection point P1. In the charging step, in a non-defective state in which main power supply 2 is not defective, first field-effect transistor SW1 is turned on, and third field-effect transistor SW3 operates in the active region in order to control the charging current flowing to power storage device 3. Accordingly, in the charging step, power storage device 3 is charged from main power supply 2 through charging path RT1 passing through first field-effect transistor SW1, second field-effect transistor SW2, and third field-effect transistor SW3. In the backup feeding step, in a defective state in which main power supply 2 is defective, first field-effect transistor SW1 is turned off, and second field-effect transistor SW2 and third field-effect transistor SW3 are turned on. Accordingly, in the backup feeding step, power is supplied from power storage device 3 to load 4. In the backup feeding step, a path through which power is supplied from power storage device 3 to load 4 may include backup path RT2 passing through third field-effect transistor SW3 and second field-effect transistor SW2 from power storage device 3. A (computer) program according to an aspect is a program for causing a computer system to execute the method for controlling backup power supply system 1.

Modifications of the above-described embodiment will be described below. The modifications described below may be appropriately combined and applied.

Backup power supply system 1 disclosed herein includes, for example, a computer system for implementing controller 10. The computer system mainly includes a processor and a memory as hardware. The processor executing the program recorded in the memory of the computer system provides the functions of backup power supply system 1 according to the present disclosure. The program may be recorded previously in the memory of the computer system, may be provided through an electric communication line, or may be provided by being recorded in a non-transitory recording medium, such as a memory card, an optical disc, or a hard disc drive readable by the computer system. The processor of the computer system includes one or more electronic circuits including a semi-conductor integrated circuit (IC) or a large-scale integrated circuit (LSI). The integrated circuits such as an IC or an LSI herein are called differently depending on the degree of integration, and include an integrated circuit called a system LSI, a very large-scale integration (VLSI), or an ultra large scale integration (ULSI). A logic device which is programmed after the production of the LSI and which allows reconfiguration of connection relationships within field-programmable gate array (FPGA) or the LSI or reconfiguration of circuit partition within the LSI can also be adopted as a processor. The plurality of electronic circuits may be integrated into one chip, or may be distributed to plural chips. The chips may be integrated into one device or may be distributed to plural devices. The computer system herein includes a microcontroller including one or more processors and one or more memories. Therefore, the microcontroller is also configured with one or more electronic circuits including a semi-conductor integrated circuit or a large-scale integrated circuit.

Controller 10 is not necessarily implemented by the computer system, and may be implemented by an analog circuit.

It is not essential for backup power supply system 1 that plural functions in backup power supply system 1 are integrated in a single housing, and the components of backup power supply system 1 may be distributed to plural housings. At least a part of the functions of backup power supply system 1, for example, some functions of controller 10 may be implemented by a cloud (cloud computing) or the like. In a case where backup power supply system 1 is mounted on vehicle 9, some functions of controller 10 may be implemented by an electronic controller (ECU) of vehicle 9.

In the above-described embodiment, in the comparison of the two values such as the voltage values, “equal to or higher than” may be “higher than”. That is, in the comparison of the two values, whether the two values are equal to each other may be changed depending on the setting order of the reference value or the like, and there is no technical difference between “equal to or higher than” and “higher than”. Similarly, “lower than” may be “equal to or lower than”, and there is no technical difference between “lower than” and “equal to or lower than”.

### (3.1) Modification 1

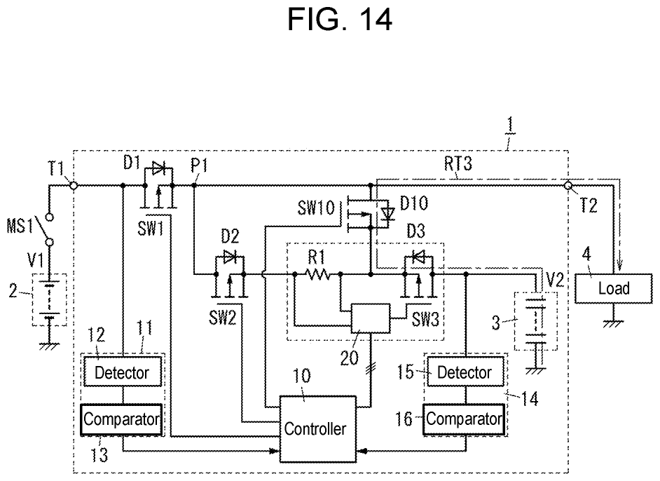

Backup power supply system 1 according to Modification 1 will be described below with reference to FIGS. 14 to 16.

Backup power supply system 1 according to Modification 1 is different from backup power supply system 1 according to Embodiment 1 in that Modification 1 further includes bypass field-effect transistor SW10. The same components as those in Embodiment 1 are denoted by the same reference marks, and description thereof is omitted.

A first end (drain) of bypass field-effect transistor SW10 is connected to second connection terminal T2, and a second end (source) of bypass field-effect transistor SW10 is connected to a terminal (source) of third field-effect transistor SW3 proximal to second field-effect transistor SW2. That is, body diode D10 of bypass field-effect transistor SW10 is connected in a direction allowing a current to flow from second connection terminal T2 to power storage device 3.

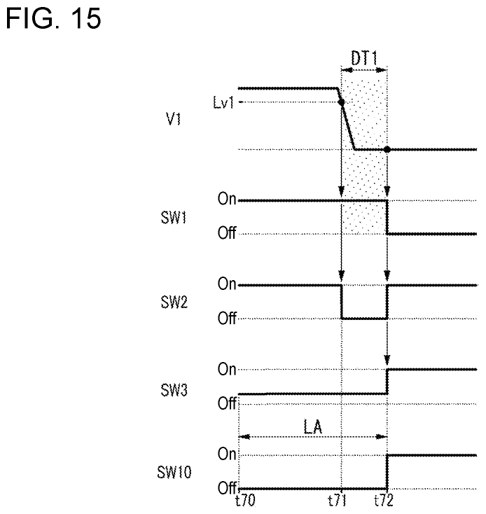

Here, an operation of backup power supply system 1 according to Modification 1 will be described below with reference to FIG. 15. An operation from time point t70 to time point t72 at which the supply of backup power is started is similar to the operation from time point t1 to time point t4 described in “(1.2.1) Operation in Case Where Defective Occurs after Completing Charging”, and therefore, description thereof will be omitted. Controller 10 turns off bypass field-effect transistor SW10 from time point t70 to time point t72.

When the defective state continues for masking period DT1 from time point t71 at which the failure of main power supply 2 is detected (time point t72), controller 10 turns off first field-effect transistor SW1 and turns on second and third field-effect transistors SW2 and SW3. In a case where power is supplied from power storage device 3 to load 4 in the defective state (that is, at time point t72), controller 10 turns on bypass field-effect transistor SW10. Accordingly, power is supplied from power storage device 3 to load 4 via backup path RT3 (see FIG. 14) passing through third field-effect transistor SW3 and bypass field-effect transistor SW10. Therefore, load 4 operates with the power supplied from power storage device 3 even in a case where the defective state occurs. Backup path RT3 does not include current detection resistor R1, consequently reducing the loss caused by current detection resistor R1.

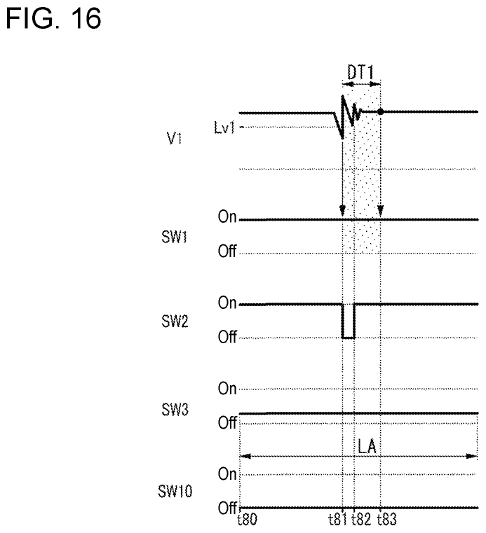

As shown in FIG. 16, when power supply voltage V1 of main power supply 2 is lower than threshold Lv1 at time point t81 but becomes equal to or higher than threshold Lv1 at time point t82 before masking period DT1 elapses, controller 10 does not perform the supply of backup power. That is, controller 10 turns on first and second field-effect transistors SW1 and SW2 and causes third field-effect transistor SW3 to operate in the active region, thereby preventing an erroneous operation of backup power supply system 1.

### (3.2) Modification 2

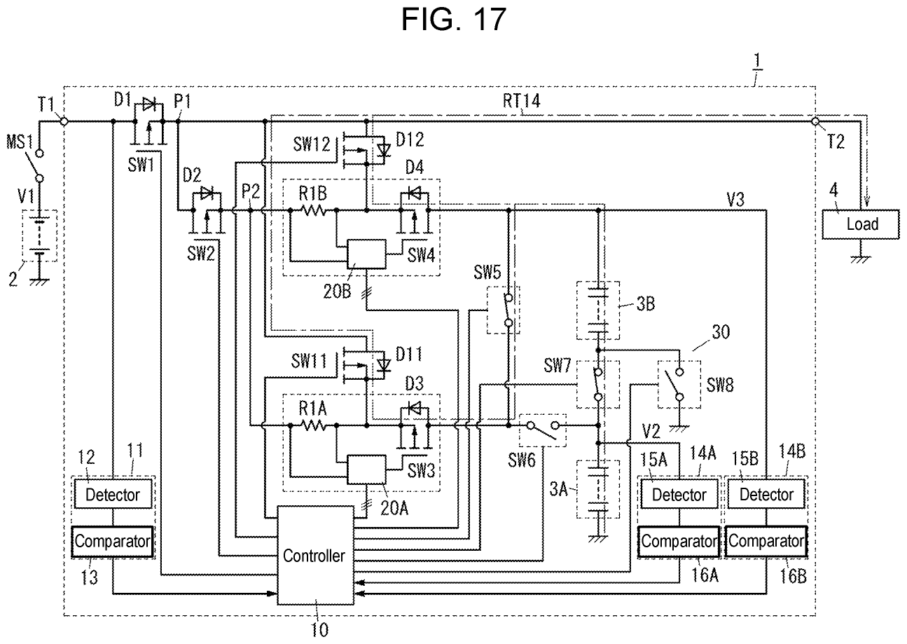

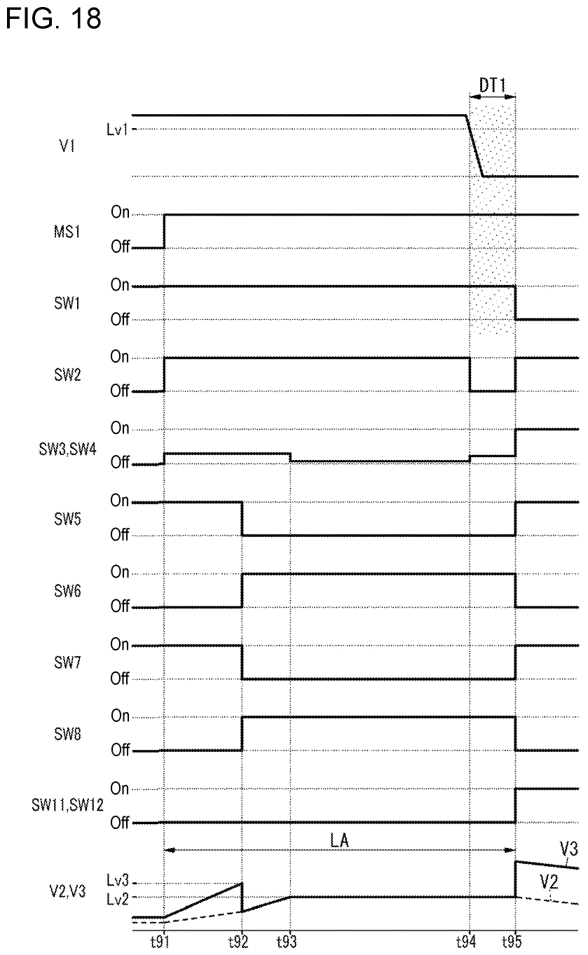

Backup power supply system 1 according to Modification 2 will be described below with reference to FIGS. 17 and 18.

Backup power supply system 1 according to Modification 2 is different from backup power supply system 1 according to Embodiment 2 in that Modification 2 further includes first bypass field-effect transistor SW11 and second bypass field-effect transistor SW12. The same components as those in Embodiment 2 are denoted by the same reference marks, and description thereof is omitted.

First bypass field-effect transistor SW11 has a first end (drain) connected to second connection terminal T2 and a second end (source) connected to a terminal (source) of third field-effect transistor SW3 proximal to second field-effect transistor SW2. Second bypass field-effect transistor SW12 has a first end (drain) connected to second connection terminal T2 and a second end (source) connected to a terminal (source) of fourth field-effect transistor SW4 proximal to second field-effect transistor SW2. That is, body diode D11 of first bypass field-effect transistor SW11 is connected in a direction allowing a current to flow from second connection terminal T2 to first power storage device 3A. Body diode D12 of second bypass field-effect transistor SW12 is connected in a direction allowing a current to flow from second connection terminal T2 to second power storage device 3B.

Here, an operation of backup power supply system 1 according to Modification 2 will be described with reference to FIG. 18. An operation from time point t91 to time point t95 at which the supply of backup power is started is similar to the operation from time point t61 to time point t65 described in “(2.2) Operation”, and therefore, description thereof will be omitted. Controller 10 turns off first and second bypass field-effect transistors SW11 and SW12 from time point t91 to time point t95.

When the defective state continues for masking period DT1 from time point t94 at which the failure of main power supply 2 is detected, controller 10 turns off first field-effect transistor SW1 and turns on second and third field-effect transistors SW2 and SW3 at time point t95. Controller 10 turns on switches SW5 and SW7, turns off switches SW6 and SW8, and switches switching circuit 30 to the second state. In a case where power is supplied from first power storage device 3A and second power storage device 3B to load 4 in the defective state, controller 10 turns on first bypass field-effect transistor SW11 and second bypass field-effect transistor SW12. Accordingly, power is supplied from first power storage device 3A and second power storage device 3B to load 4 via backup path RT14 (see FIG. 17) passing through a parallel circuit in which a series circuit of third field-effect transistor SW3 and first bypass field-effect transistor SW11 connected in series to each other is connected in parallel to a series circuit of fourth field-effect transistor SW4 and second bypass field-effect transistor SW12 connected in series to each other. Therefore, load 4 operates with the power supplied from first power storage device 3A and second power storage device 3B even in a case where the defective state occurs. Current detection resistors R1A and R1B are not included in backup path RT14, consequently reducing the loss caused by current detection resistors R1A and R1B.

In Modification 2, the first bypass field-effect transistor SW11 is not essential and may be omitted as appropriate. In this case, power may be supplied from first power storage device 3A and second power storage device 3B connected in series to load 4 via second bypass field-effect transistor SW12.

### (3.3) Modification 3

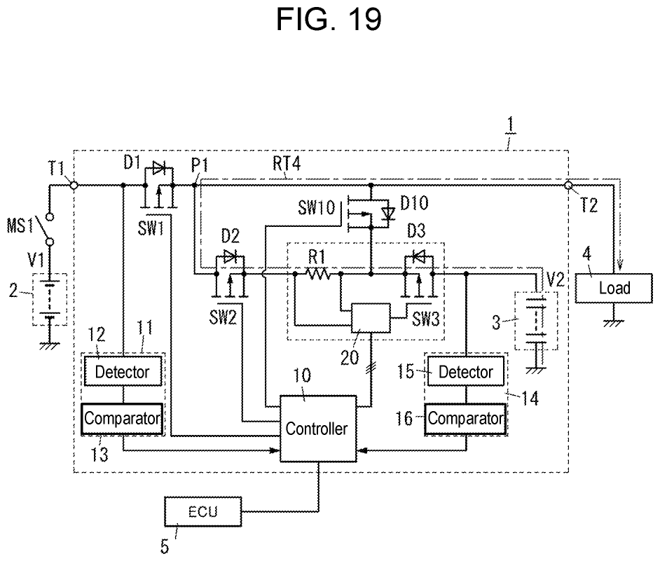

Backup power supply system 1 according to Modification 3 will be described below with reference to FIGS. 19 to 22.

Backup power supply system 1 according to Modification 3 is different from that according to Modification 1 in that the feeding path is changed according to the type of load 4 in a case where power is supplied from power storage device 3 to load 4 in the defective state. The same components as those of above-described Modification 1 are denoted by the same reference marks, and description thereof is omitted.

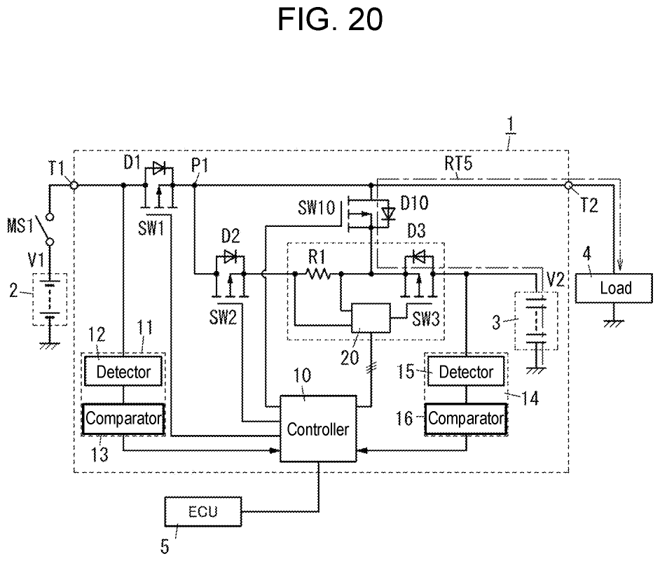

Controller 10 switches the feeding path to load 4 to either first path RT4 (see FIG. 19) or second path RT5 (see FIG. 20) in the defective state based on load information indicating whether load 4 is a capacitive load or a resistive load. First path RT4 is a path through which power is supplied from power storage device 3 to load 4 via third field-effect transistor SW3 and second field-effect transistor SW2. Second path RT5 is a path through which power is supplied from power storage device 3 to load 4 via bypass field-effect transistor SW10. More specifically, in accordance with the present embodiment, first path RT4 is a path through which power is supplied from power storage device 3 to load 4 via third field-effect transistor SW3, current detection resistor R1, and second field-effect transistor SW2. Second path RT5 is a path through which power is supplied from power storage device 3 to load 4 via third field-effect transistor SW3 and bypass field-effect transistor SW10.

Load 4 on which backup power supply system 1 performs the supply of backup power (in other words, load 4 that is a target on which the supply of backup power is to be performed) includes at least one of a capacitive load and a resistive load. Examples of the capacitive load include a DC-DC converter having a capacitance component, such as an electrolytic capacitor for smoothing at an input stage. Examples of the resistive load include a motor having a winding which is a resistance component. Controller 10 acquires, from ECU 5 of vehicle 9, load information on load 4 that is a target on which the supply of backup power is to be performed, for example. Controller 10 is configured to periodically communicate with ECU 5 to acquire the load information from ECU 5. The load information indicates whether load 4 is a capacitive load or a resistive load, and may be information on the name or type of load 4, or may be type information indicating whether load 4 is a capacitive load or a resistive load. In a case where the load information is information on the name (for example, a motor or a DC-DC converter) or the type of load 4, controller 10 may determine whether load 4 is a capacitive load or a resistive load based on the load information.

For example, in a case where load 4 is a capacitive load, a large inrush current may flow into the capacitive load from power storage device 3 at the start of the supply of backup power. Therefore, in a case where load 4 is a capacitive load, controller 10 preferably causes a path through which power is supplied from power storage device 3 to load 4 to be first path RT4. Since first path RT4 includes current detection resistor R1, first path RT4 has a path resistance larger than that of second path RT5. Therefore, an inrush current is prevented from flowing into load 4 by supplying power from power storage device 3 to load 4 that is a capacitive load via first path RT4.

On the other hand, in a case where load 4 is a resistive load, particularly in a case where load 4 is a motor or the like, a large amount of power is required, and therefore, the resistance of the feeding path to load 4 is preferably reduced as much as possible.

Therefore, in a case where load 4 is a resistive load, controller 10 preferably causes the path through which power is supplied from power storage device 3 to load 4 to be second path RT5. Second path RT5 is a path through which power is supplied from power storage device 3 to load 4 via third field-effect transistor SW3 and bypass field-effect transistor SW10. Second path RT5 has a path resistance smaller than that of first path RT4. Therefore, the loss caused by path resistance can be reduced.

In a case where load 4 is a capacitive load, controller 10 may preferably switch the feeding path to first path RT4 from the occurrence of the defective state until a switching condition is satisfied, and switches the feeding path to second path RT5 when the switching condition is satisfied.

In a case where load 4 is a capacitive load, a large inrush current flows into load 4 at the start of the supply of backup power, and the current flowing to load 4 decreases with time. Therefore, controller 10 causes the path through which power is supplied from power storage device 3 to load 4 to be first path RT4 from the occurrence of the defective state until the switching condition is satisfied, so that a large inrush current may be prevented from flowing into load 4. When the switching condition is satisfied, controller 10 causes the path through which power is supplied from power storage device 3 to load 4 to be second path RT5 so as to reduce the loss caused by the path resistance.

The above-described switching condition preferably includes at least one of a condition that a certain period of time has elapsed from the occurrence of the defective state, a condition that the discharging current from power storage device 3 is equal to or lower than a threshold current, a condition that charging voltage V2 of power storage device 3 is equal to or lower than the threshold voltage, and a condition that a state of charge of power storage device 3 is equal to or lower than a threshold. When at least one of these conditions is satisfied, the inrush current flowing into load 4 is smaller than the case where all the conditions are not satisfied, and reduces the possibility that a large inrush current flows into a circuit including load 4.

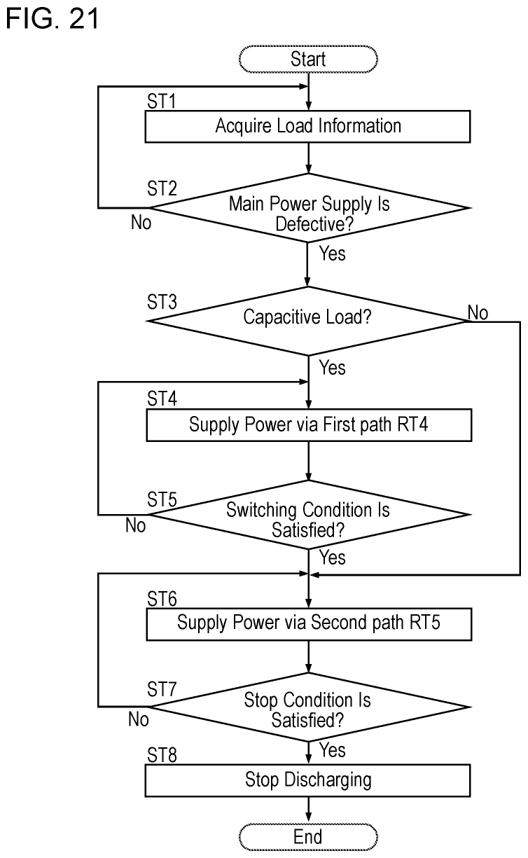

Here, an operation of the device in a case where the above-described switching condition includes the condition that a certain period of time elapses from the occurrence of the defective state and the condition that the discharging current from power storage device 3 is equal to or lower than the threshold current will be described with reference to FIG. 21.

Controller 10 is configured to periodically communicate with ECU 5 of the vehicle and acquires load information from ECU 5 (step ST1). The load information includes, for example, information on the name of load 4 on which the supply of backup power is to be performed. A memory of controller 10 stores information indicating whether load 4 is a capacitive load or a resistive load in association with the name of load 4. Therefore, based on the load information (the name of load 4) acquired from ECU 5, controller 10 determines whether load 4 that is a target on which the supply of backup power is to be performed is a capacitive load or a resistive load.

After that, when main power supply 2 is defective (step ST2: Yes), controller 10 determines whether or not load 4 that is a target on which the supply of backup power is to be performed is a capacitive load (step ST3).

If load 4 that is a target on which the supply of backup power is to be performed is a capacitive load (step ST3: Yes), controller 10 turns off first field-effect transistor SW1, turns on second and third field-effect transistors SW2 and SW3, and turns off bypass field-effect transistor SW10 after masking period DT1 elapses. Then, power is supplied from power storage device 3 to load 4 via first path RT4 (step ST4). First path RT4 includes current detection resistor R1, and prevents an inrush current from flowing into load 4 to protects the circuit including load 4. Power is supplied from power storage device 3 to load 4 via first path RT4, and therefore, load 4 continuously operates even in the defective state.

After that, when a certain period of time elapses from the occurrence of the defective state, or when the discharging current from power storage device 3 becomes equal to or lower than the threshold current, controller 10 determines that the switching condition is satisfied (step ST5: Yes), and controller 10 turns on bypass field-effect transistor SW10. Then, power is supplied from power storage device 3 to load 4 via second path RT5 (step ST6), and therefore, the loss caused by path resistance is reduced.

Upon determining that load 4 that is a target on which the supply of backup power is to be performed is a resistive load in the determination at step ST3 (step ST3: No), controller 10 turns off first field-effect transistor SW1, turns on second and third field-effect transistors SW2 and SW3, and turns on bypass field-effect transistor SW10 after masking period DT1 elapses. Then, power is supplied from power storage device 3 to load 4 via second path RT5 (step ST6). In a case where load 4 is a resistive load, particularly in a case where load 4 is a motor or the like, a large amount of power is required, and therefore, the resistance of the feeding path to load 4 is preferably reduced as much as possible. Accordingly, controller 10 supplies power to load 4 via second path RT5 from the start of the supply of backup power, so that the loss caused by the path resistance of the feeding path can be reduced, and large power can be supplied to load 4.

When the supply of backup power in second path RT5 is started in step ST6, controller 10 determines whether or not a stop condition for stopping the supply of backup power is satisfied (step ST7). The stop condition may include, for example, a condition that charging voltage V2 of power storage device 3 is equal to or lower than a predetermined over-discharge level. When the voltage value of charging voltage V2 detected by charging voltage detection unit 14 is higher than the over-discharge level, controller 10 determines that the stop condition is not satisfied (step ST7: No), and continuously supplies power to load 4 via second path RT5. On the other hand, when the voltage value of charging voltage V2 detected by charging voltage detection unit 14 becomes equal to or lower than the over-discharge level, controller 10 determines that the stop condition is satisfied (step ST7: Yes), turns off first to third field-effect transistors SW1, SW2, and SW3, turns off bypass field-effect transistor SW10, stops the discharging from power storage device 3 (step ST8), and stops the power supplied from power storage device 3 to load 4.

As described above, a method for controlling backup power supply system 1 according to Modification 3 further includes a switching step. In the switching step, the feeding path to load 4 is switched to either first path RT4 or second path RT5 in the defective state based on the load information indicating whether load 4 is a capacitive load or a resistive load. First path RT4 is a path through which power is supplied from power storage device 3 to load 4 via third field-effect transistor SW3 and second field-effect transistor SW2. Second path RT5 is a path through which power is supplied from power storage device 3 to load 4 via bypass field-effect transistor SW10. Bypass field-effect transistor SW10 has a first end connected to second connection terminal T2 and a second end connected to a terminal of third field-effect transistor SW3 proximal to second field-effect transistor SW2.

Controller 10 may store, in a memory included in controller 10, power supplying target information indicating whether load 4 on which the supply of backup power has been previously performed is a capacitive load or a resistive load. In a case where the load information cannot be acquired from ECU 5 due to a communication failure or the like in step ST1, controller 10 may determine whether load 4 on which the supply of backup power is to be performed is a capacitive load or a resistive load based on the power supplying target information read from the memory.

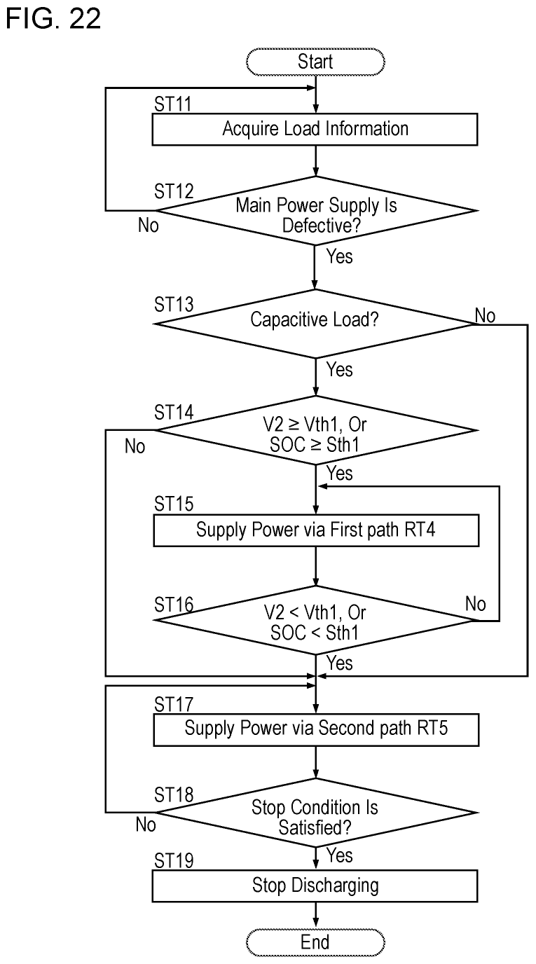

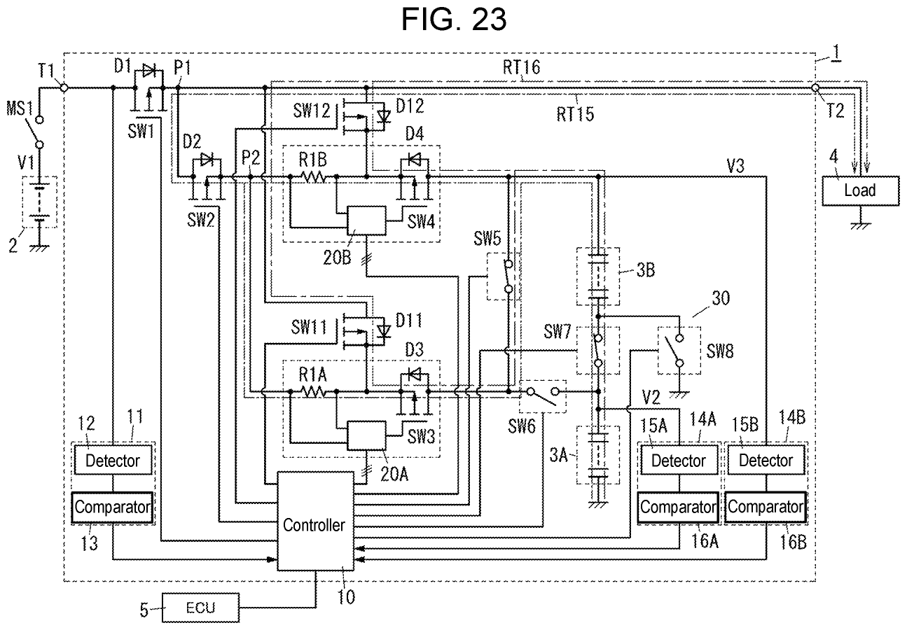

The switching condition may be appropriately changed, and may include a condition (hereinafter, referred to as a first condition) that charging voltage V2 of power storage device 3 is equal to or lower than threshold voltage Vth1 and a condition (hereinafter, referred to as a second condition) that a state of charge SOC of power storage device 3 is equal to or lower than threshold Sth1. An operation of the device in a case where the switching condition includes the first condition and the second condition will be described with reference to FIG. 22.

Controller 10 periodically communicates with ECU 5 of the vehicle and acquires load information from ECU 5 (step ST11). The load information includes, for example, information on the name of load 4 that is a target on which the supply of backup power is to be performed, and controller 10 determines whether load 4 that is a target on which the supply of backup power is to be performed is a capacitive load or a resistive load based on the load information (the name of load 4) acquired from ECU 5.

After that, when main power supply 2 is defective (step ST12: Yes), controller 10 determines whether load 4 that is a target on which the supply of backup power is to be performed is a capacitive load (step ST13).

When load 4 that is a target on which the supply of backup power is to be performed is a capacitive load (step ST13: Yes), controller 10 determines whether or not the first condition and the second condition are satisfied after masking period DT1 elapses. If at least one of the first condition and the second condition is not satisfied, controller 10 turns off first field-effect transistor SW1, turns on second and third field-effect transistors SW2 and SW3, and turns off bypass field-effect transistor SW10. That is, when charging voltage V2 of power storage device 3 is equal to or higher than threshold voltage Vth1 or the state of charge SOC of power storage device 3 is equal to or higher than threshold value Sth1 (step ST14: Yes), controller 10 causes power to be supplied from power storage device 3 to load 4 via first path RT4 (step ST15). First path RT4 includes current detection resistor R1, hence preventing an inrush current from flowing into load 4 protecting the circuit including load 4.

Controller 10 monitors charging voltage V2 and the state of charge SOC of power storage device 3. If at least one of the first condition and the second condition is not satisfied (step ST16: No), controller 10 causes power storage device 3 to supply power to load 4 via first path RT4 (step ST15). That is, when charging voltage V2 of power storage device 3 is equal to or higher than threshold voltage Vth1, or when state of charge SOC of power storage device 3 is equal to or higher than threshold Sth1, power is supplied from power storage device 3 to load 4 via first path RT4.

On the other hand, when both the first condition and the second condition are satisfied, that is, when charging voltage V2 of power storage device 3 becomes lower than threshold voltage Vth1 and the state of charge SOC of power storage device 3 becomes lower than threshold Sth1 (step ST16: Yes), controller 10 turns on bypass field-effect transistor SW10. Then, power is supplied from power storage device 3 to load 4 via second path RT5 (step ST17). Second path RT5 is a path through which power is supplied from power storage device 3 to load 4 via third field-effect transistor SW3 and bypass field-effect transistor SW10. Second path RT5 has a path resistance smaller than that of first path RT4, hence reducing the loss caused by path resistance.

Upon determining that load 4 that is a target on which the supply of backup power is to be performed is a resistive load in the determination of step ST13 (step ST13: No), controller 10 turns off first field-effect transistor SW1, turns on second and third field-effect transistors SW2 and SW3, and turns on bypass field-effect transistor SW10. Then, power is supplied from power storage device 3 to load 4 via second path RT5 (step ST17).

When both the first condition and the second condition are satisfied, that is, when charging voltage V2 of power storage device 3 becomes lower than threshold voltage Vth1 and state of charge SOC of power storage device 3 becomes lower than threshold Sth1 in the determination of step ST14 (step ST14: No), first field-effect transistor SW1 is turned off, second and third field-effect transistors SW2 and SW3 are turned on, and bypass field-effect transistor SW10 is turned on. When charging voltage V2 is lower than threshold voltage Vth1 and the state of charge SOC of power storage device 3 is lower than threshold Sth1, a large inrush current is unlikely to flow into load 4. Therefore, controller 10 causes the path through which power is supplied from power storage device 3 to load 4 to be second path RT5. Then, since power is supplied from power storage device 3 to load 4 via second path RT5 (step ST17), the loss caused by the path resistance is reduced while preventing the inrush current flowing into load 4.

When the supply of backup power in second path RT5 is started in step ST17, controller 10 determines whether or not a stop condition for stopping the supply of backup power is satisfied (step ST18). Here, the stop condition may include, for example, a condition that charging voltage V2 of power storage device 3 is equal to or lower than a predetermined reference voltage and a condition that the state of charge SOC of power storage device 3 is equal to or lower than a predetermined reference ratio. Here, the reference voltage is set to a value lower than above-described threshold voltage Vth1, and the reference ratio is set to a value lower than above-described threshold Sth1. When charging voltage V2 becomes equal to or lower than the reference voltage or state of charge SOC becomes equal to or lower than the reference ratio, controller 10 determines that the stop condition is satisfied (step ST18: Yes), turns off first to third field-effect transistors SW1, SW2, and SW3, and turns off bypass field-effect transistor SW10 to stop the discharging from power storage device 3 (step ST19) and stop the supply of power from power storage device 3 to load 4. The stop condition does not necessarily include the condition that charging voltage V2 of power storage device 3 is equal to or lower than the reference voltage and the condition that the state of charge SOC of power storage device 3 is equal to or lower than the reference ratio, and may include only one of these conditions. The stop condition is not limited to the above-described condition, and the stop condition may include a condition that the discharging current from power storage device 3 is equal to or lower than a predetermined reference current.

In Modification 1 and Modification 3, bypass field-effect transistor SW10 may be connected between second connection terminal T2 and the connection point of third field-effect transistor SW3 and power storage device 3. In this case, second path RT5 is a path through which power is supplied from power storage device 3 to load 4 via bypass field-effect transistor SW10.

### (3.4) Modification 4

Backup power supply system 1 according to Modification 4 will be described below with reference to FIG. 23.

Backup power supply system 1 according to Modification 4 is different from that according to Modification 2 in that the feeding path is changed according to the type of load 4 in a case where power is supplied from power storage device 3 to load 4 in the defective state. The same components as those of above-described Modification 2 are denoted by the same reference marks, and description thereof is omitted.

In the present modification, similarly to Modification 3, controller 10 switches the feeding path to the load to either first path RT15 or second path RT16 in the defective state based on the load information indicating whether load 4 is a capacitive load or a resistive load (see FIG. 23). First path RT15 is a path through which power is supplied from first power storage device 3A and second power storage device 3B connected in series to each other to load 4 via third field-effect transistor SW3, fourth field-effect transistor SW4, and second field-effect transistor SW2. Second path RT16 is a path through which power is supplied from first power storage device 3A and second power storage device 3B connected in series to each other to load 4 via at least one of a series circuit of first bypass field-effect transistor SW11 and third field-effect transistor SW3 connected in series to each other and a series circuit of second bypass field-effect transistor SW12 and fourth field-effect transistor SW4 connected in series to each other.

In a case where load 4 is a capacitive load, controller 10 preferably switches the feeding path to first path RT15 from the occurrence of the defective state until the switching condition is satisfied, and switches the feeding path to second path RT16 when the switching condition is satisfied.

In a case where load 4 is a capacitive load, a large inrush current may flow into load 4 at the start of the supply of backup power, and the current flowing to load 4 decreases with time. Therefore, controller 10 sets the path through which power is supplied from power storage device 3 to load 4 to first path RT15 from the occurrence of the defective state until the switching condition is satisfied so as to prevent a large inrush current from flowing into load 4. When the switching condition is satisfied, controller 10 causes the path through which power is supplied from power storage device 3 to load 4 to be second path RT16 so as to reduce the loss due to the path resistance.

The above-described switching condition preferably includes at least one of a condition that a certain period of time has elapsed from the occurrence of the defective state, a condition that the discharging current from first power storage device 3A and second power storage device 3B is equal to or lower than a threshold current, a condition that the sum of the charging voltages of first power storage device 3A and second power storage device 3B is equal to or lower than a threshold voltage, and a condition that the state of charge of first power storage device 3A and second power storage device 3B is equal to or lower than a threshold. The sum of the charging voltages of first power storage device 3A and second power storage device 3B is charging voltage V3 while first power storage device 3A and second power storage device 3B are connected in series to each other. The state of charge of first power storage device 3A and second power storage device 3B is a ratio of a total value of charging amounts of first power storage device 3A and second power storage device 3B to a total value of charging capacities of first power storage device 3A and second power storage device 3B. If at least one of these conditions is satisfied, the inrush current flowing into load 4 is smaller than the case where all the conditions are not satisfied, and the possibility of overcurrent flowing into the circuit including load 4 can be reduced.

In Modification 4, it is not essential to provide both first bypass field-effect transistor SW11 and second bypass field-effect transistor SW12, and only one of first bypass field-effect transistor SW11 and second bypass field-effect transistor SW12 may be provided. In this case, power may be supplied from first power storage device 3A and second power storage device 3B connected in series to each other to load 4 via either a series circuit of first bypass field-effect transistor SW11 and third field-effect transistor SW3 connected in series to each other or a series circuit of second bypass field-effect transistor SW12 and fourth field-effect transistor SW4 connected in series to each other.

In Modification 2 and Modification 4, first bypass field-effect transistor SW11 may be connected to each other between second connection terminal T2 and a terminal of third field-effect transistor SW3 proximal to first power storage device 3A. Second bypass field-effect transistor SW12 may be connected between second connection terminal T2 and a connection point of fourth field-effect transistor SW4 and second power storage device 3B. In this case, power is supplied from first power storage device 3A and second power storage device 3B connected in series to each other to load 4 via first bypass field-effect transistor SW11 or second bypass field-effect transistor SW12.

### (3.5) Other Modifications

In the above-described embodiment, power storage device 3 may be a secondary battery, such as a lithium ion capacitor (LIC) or a lithium ion battery (LIB). In the lithium ion capacitor, a positive electrode is formed of the same material (for example, active carbon) as that of the EDLC, and a negative electrode is formed of the same material (for example, a carbon material such as graphite) as that of the LIB.

Power storage device 3 is not necessarily an electrical double layer capacitor, and may be, for example, an electrochemical device having a configuration described below. The electrochemical device herein includes a positive electrode, a negative electrode, and a non-aqueous electrolyte. The positive electrode includes a positive electrode current collector and a positive electrode material layer held on the positive electrode current collector and containing a positive-electrode active material. The positive-electrode material layer contains a conductive polymer as a positive electrode active material which is doped or dedoped with anions (dopants). The negative electrode includes a negative electrode material layer containing a negative-electrode active material. The negative-electrode active material is, for example, a material in which an oxidation-reduction reaction accompanied by intercalation and desorption of lithium ions proceeds, and specific examples thereof include a carbon material, a metal compound, an alloy, and a ceramic material. The non-aqueous electrolyte has lithium ion conductivity as an example. This type of non-aqueous electrolyte contains lithium salt and non-aqueous solution in which the lithium salt is dissolved. The electrochemical device having such a configuration has an energy density higher than that of an electrical double layer capacitor or the like.

### Summary

As described above, a backup power supply system (1) according to a first aspect includes a first connection terminal (T1), a second connection terminal (T2), a first field-effect transistor (SW1), a series circuit of a second field-effect transistor (SW2) and a third field-effect transistor (SW3), and a controller (10). The first connection terminal (T1) is configured to be connected to a main power supply (2). The second connection terminal (T2) is configured to be connected to a load (4). The first field-effect transistor (SW1) is connected between the first connection terminal (T1) and the second connection terminal (T2). The series circuit of a second field-effect transistor (SW2) and a third field-effect transistor (SW3) is connected between a power storage device (3) and a connection point (P1) of the first field-effect transistor (SW1) and the second connection terminal (T2). A body diode included in the second field-effect transistor (SW2) is connected in a direction allowing a current to flow from the connection point (P1) to the power storage device (3). A body diode included in the third field-effect transistor (SW3) is connected in a direction allowing a current to flow from the power storage device (3) to the connection point (P1). In a non-defective state in which the main power supply (2) is not defective, the controller (10) is configured to turn on the first field-effect transistor (SW1) and cause the third field-effect transistor (SW3) to operate in an active region so as to cause a charging current flowing to the power storage device (3), thereby charging the power storage device (3) via a charging path from the main power supply (2) through the first field-effect transistor (SW1), the second field-effect transistor (SW2), and the third field-effect transistor (SW3). In a defective state in which the main power supply (2) is defective, the controller (10) is configured to turn off the first field-effect transistor (SW1) and turn on the second field-effect transistor (SW2) and the third field-effect transistor (SW3), thereby supplying power from the power storage device (3) to the load (4).

According to this aspect, the backup power supply system (1) prevents a voltage supplied to the load (4) from decreasing in a case where the supply of backup power is performed.

In the backup power supply system (1) according to a second aspect in conjunction with the first aspect, the controller (10) is configured to turn on first field-effect transistor (SW1) and turn off the second field-effect transistor (SW2) and the third field-effect transistor (SW3) when the defective state occurs, and the controller (10) is configured to turn off the first field-effect transistor (SW1) and turn on the second field-effect transistor (SW2) and the third field-effect transistor (SW3) when the defective state continues for a predetermined masking period (DTI).

According to this aspect, the system reduces the possibility that the supply of backup power is performed in a case where a defective occurs for a period shorter than the masking period (DTI).

In the backup power supply system (1) according to a third aspect in conjunction with the first or second aspect, in the non-defective state, the controller (10) is configured to perform a current control by causing the third field-effect transistor (SW3) to operate in a saturation region or an active region so as to cause the charging voltage of the power storage device (3) to reach the target voltage value in a first period until a charging voltage of the power storage device (3) reaches a target voltage value. In the non-defective state, the controller (10) is configured to perform a voltage control by causing the third field-effect transistor (SW3) to operate in the active region so as to maintain the charging voltage of the power storage device (3) at the target voltage value in a second period after the first period.

According to this aspect, the power storage device (3) is efficiently charged.

The backup power supply system (1) according to a fourth aspect in conjunction with any one of the first to third aspects further includes a driver circuit (20) configured to drive the third field-effect transistor (SW3). The driver circuit (20) includes a first drive circuit (21), a second drive circuit (22), and a third drive circuit (23). The first drive circuit (21) is configured to cause the third field-effect transistor (SW3) to operate in the active region based on a current command value input from the controller (10) and a voltage across a current detection resistor (R1) connected between the connection point (P1) and the power storage device (3). The second drive circuit (22) is configured to turn on the third field-effect transistor (SW3) based on an On-signal input from the controller (10). The third drive circuit (23) is configured to turn off the third field-effect transistor (SW3) based on an Off-signal input from the controller (10).

According to this aspect, the third field-effect transistor (SW3) may be turned on and off and operate in the active region.

The backup power supply system (1) according to a fifth aspect in conjunction with any one of the first to fourth aspects further includes a bypass field-effect transistor (SW10). The bypass field-effect transistor (SW10) has a first end connected to the second connection terminal (T2) and a second end connected to a terminal of the third field-effect transistor (SW3) proximal to the second field-effect transistor (SW2). In a case where power is supplied from the power storage device (3) to the load (4) in the defective state, the controller (10) is configured to turn on the bypass field-effect transistor (SW10).

According to this aspect, the supply of backup power is performed through a path that does not include a current detection resistor, and the loss caused by the supply of backup power is reduced.

In the backup power supply system (1) according to a sixth aspect in conjunction with the fifth aspect, the controller (10) is configured to switch a feeding path to the load (4) to either a first path (RT4) or a second path (RT5) in the defective state based on load information indicating whether the load (4) is a capacitive load or a resistive load. The first path (RT4) is a path through which power is supplied from the power storage device (3) to the load (4) via the third field-effect transistor (SW3) and the second field-effect transistor (SW2). The second path (RT5) is a path through which power is supplied from the power storage device (3) to the load (4) via the bypass field-effect transistor (SW10).

According to this aspect, an inrush current is prevented by supplying power to the load (4) via the first path (RT4), and the loss caused by the path resistance is reduced by supplying power to the load (4) via the second path (RT5).

In the backup power supply system (1) according to a seventh aspect in conjunction with the sixth aspect, in a case where the load (4) is a capacitive load, the controller (10) is configured to switch the feeding path to the first path (RT4) from an occurrence of the defective state until a switching condition is satisfied, and switches the feeding path to the second path (RT5) when the switching condition is satisfied.

According to this aspect, the inrush current is prevented by supplying power to the load (4) via the first path (RT4) from the occurrence of the defective state until the switching condition is satisfied. When the switching condition is satisfied, the loss caused by the path resistance is reduced by supplying power to the load (4) via the second path (RT5).

In the backup power supply system (1) according to an eighth aspect in conjunction with the seventh aspect, the switching condition includes at least one of a condition that a certain period elapses from the occurrence of the defective state, a condition that a discharging current from the power storage device (3) is equal to or lower than a threshold current, a condition that a charging voltage of the power storage device (3) is equal to or lower than a threshold voltage, and a condition that a state of charge of the power storage device (3) is equal to or lower than a threshold.

According to this aspect, the loss caused by the path resistance is reduced while preventing the inrush current.

The backup power supply system (1) according to a ninth aspect in conjunction with any one of the first to fourth aspects further includes a second power storage device (3B) different from a first power storage device (3A) which is the power storage device (3), a fourth field-effect transistor (SW4), and a switching circuit (30). The fourth field-effect transistor (SW4) is connected between the second power storage device (3B) and a terminal of the second field-effect transistor (SW2) proximal to the third field-effect transistor (SW3). In a case where the second power storage device (3B) is charged in the non-defective state, the controller (10) is configured to cause the fourth field-effect transistor (SW4) to operate in an active region so as to control a charging current flowing to the second power storage device (3B). In a case where power is supplied from the second power storage device (3B) to the load (4) in the defective state, the controller (10) is configured to turn on the fourth field-effect transistor (SW4). The switching circuit (30) is configured to be switched between a first state and a second state in response to a switching signal from the controller (10). The first state is a state in which a series circuit of the third field-effect transistor (SW3) and the first power storage device (3A) is connected in parallel to a series circuit of the fourth field-effect transistor (SW4) and the second power storage device (3B) between the second field-effect transistor (SW2) and a reference potential. The second state is a state in which the first power storage device (3A) is connected in series to the second power storage device (3B) between the second field-effect transistor (SW2) and the reference potential via a parallel circuit of the third field-effect transistor (SW3) and the fourth field-effect transistor (SW4). In a case where the first power storage device (3A) and the second power storage device (3B) are charged in the non-defective state, the switching circuit (30) is configured to be switched to the first state in response to the switching signal. In a case where power is supplied from the first power storage device (3A) and the second power storage device (3B) to the load (4) in the defective state, the switching circuit (30) is configured to be switched to the second state in response to the switching signal.

According to this aspect, the first power storage device (3A) and the second power storage device (3B) are charged in the first state in which the first power storage device (3A) and the second power storage device (3B) are connected in parallel to the main power supply (2). Therefore, the first power storage device (3A) and the second power storage device (3B) are charged to the same level as the power supply voltage (V1) of main power supply (2). The supply of backup power is performed in the second state in which the first power storage device (3A) and the second power storage device (3B) are connected in series to each other. Therefore, a voltage higher than a charging voltage of each of the first power storage device (3A) and the second power storage device (3B) is supplied to the load (4).

In the backup power supply system (1) according to a tenth aspect in conjunction with the ninth aspect, in a case where the first power storage device (3A) and the second power storage device (3B) are charged in the non-defective state, the controller (10) is configured to output the switching signal for switching the switching circuit (30) to the second state, and charge the first power storage device (3A) and the second power storage device (3B) in the second state. When charging voltages of the first power storage device (3A) and the second power storage device (3B) connected in series to each other reach a predetermined switching voltage value, the controller (10) is configured to output the switching signal for switching the switching circuit (30) to the first state, and charge the first power storage device (3A) and the second power storage device (3B) in the first state.

According to this aspect, a charging time of the first power storage device (3A) and the second power storage device (3B) is shortened, thus performing the charging efficiently.

The backup power supply system (1) according to an eleventh aspect in conjunction with the ninth or tenth aspect further includes a first bypass field-effect transistor (SW11) and a second bypass field-effect transistor (SW12). The first bypass field-effect transistor (SW11) has a first end connected to the second connection terminal (T2) and a second end connected to a terminal of the third field-effect transistor (SW3) proximal to the second field-effect transistor (SW2). The second bypass field-effect transistor (SW12) has a first end connected to the second connection terminal (T2) and a second end connected to a terminal of the fourth field-effect transistor (SW4) proximal to the second field-effect transistor (SW2). In a case where power is supplied from the first power storage device (3A) and the second power storage device (3B) to the load (4) in the defective state, the controller (10) is configured to turn on the first bypass field-effect transistor (SW11) and the second bypass field-effect transistor (SW12).

According to this aspect, the supply of backup power is performed through a path that does not pass through the current detection resistor, and the loss caused by the supply of backup power can be reduced.

In the backup power supply system (1) according to a twelfth aspect in conjunction with the eleventh aspect, the controller (10) is configured to switch a feeding path to the load (4) to either a first path (RT15) or a second path (RT16) in the defective state based on load information indicating whether the load (4) is a capacitive load or a resistive load. The first path (RT15) is a path through which power is supplied from the first power storage device (3A) and the second power storage device (3B) connected in series to each other to the load (4) via the third field-effect transistor (SW3), the fourth field-effect transistor (SW4), and the second field-effect transistor (SW2). The second path (RT16) is a path through which power is supplied from the first power storage device (3A) and the second power storage device (3B) connected in series to the load (4) via at least one of a series circuit of the first bypass field-effect transistor (SW11) and the third field-effect transistor (SW3) and a series circuit of the second bypass field-effect transistor (SW12) and the fourth field-effect transistor (SW4).

According to this aspect, the inrush current is prevented by supplying power to the load (4) via the first path (RT15), and the loss caused by the path resistance is reduced by supplying power to the load (4) via the second path (RT16).

In the backup power supply system (1) according to a thirteenth aspect in conjunction with the twelfth aspect, in a case where the load (4) is a capacitive load, the controller (10) is configured to switch the feeding path to the first path (RT15) from an occurrence of the defective state until a switching condition is satisfied, and switch the feeding path to the second path (RT16) when the switching condition is satisfied.

According to this aspect, the inrush current is prevented by supplying power to the load (4) via the first path (RT15) from the occurrence of the defective state until the switching condition is satisfied. When the switching condition is satisfied, the loss caused by the path resistance is reduced by supplying power to the load (4) via the second path (RT16).

In the backup power supply system (1) according to a fourteenth aspect in conjunction with the thirteenth aspect, the switching condition includes at least one of a condition that a certain period elapses from the occurrence of the defective state, a condition that discharging currents from the first power storage device (3A) and the second power storage device (3B) are equal to or lower than a threshold current, a condition that a sum of charging voltages of the first power storage device (3A) and the second power storage device (3B) is equal to or lower than a threshold voltage, and a condition that a state of charge of the first power storage device (3A) and the second power storage device (3B) is equal to or lower than a threshold value.

According to this aspect, the loss caused by the path resistance is reduced while preventing the inrush current.

A movable object (9) according to a fifteenth aspect includes the backup power supply system according to any one of claims 1 to 14 and a main movable body (91). The main movable body (91) has the backup power supply system, the main power supply (2), and the load (4) mounted thereon.

According to this aspect, the movable object prevents the voltage supplied to load (4) from decreasing in the supply of backup power.

A method for controlling the backup power supply system (1) according to a sixteenth aspect includes a charging step and a backup feeding step. The backup power supply system includes a first connection terminal (T1) connected to a main power supply (2), a second connection terminal (T2) connected to a load (4), a first field-effect transistor (SW1) connected between the first connection terminal (T1) and the second connection terminal (T2), and a series circuit of a second field-effect transistor (SW2) and a third field-effect transistor (SW3), the series circuit being connected between a power storage device (3) and a connection point (P1) of the first field-effect transistor (SW1) and the second connection terminal (T2), wherein a body diode included in the second field-effect transistor (SW2) is connected in a direction allowing a current to flow from the connection point (P1) to the power storage device (3), and a body diode included in the third field-effect transistor (SW3) is connected in a direction allowing a current to flow from the power storage device (3) to the connection point (P1). In the charging step, in a non-defective state in which the main power supply (2) is not defective, the power storage device (3) is charged from the main power supply (2) via a charging path through the first field-effect transistor (SW1), the second field-effect transistor (SW2), and the third field-effect transistor (SW3) by turning on the first field-effect transistor (SW1) and by causing the third field-effect transistor (SW3) to operate in an active region so as to control a charging current flowing to the power storage device (3). In the backup feeding step, in a defective state in which the main power supply (2) is defective, power is supplied from the power storage device (3) to the load (4) by turning off the first field-effect transistor (SW1) and turning on the second field-effect transistor (SW2) and the third field-effect transistor (SW3).

According to this aspect, this method prevents a decrease in the voltage supplied to load (4) in a case where the supply of backup power is performed.

The method for controlling the backup power supply system (1) according to a seventeenth aspect in conjunction with the sixteenth aspect further includes a switching step of switching a feeding path to the load (4) to either a first path (RT4) or a second path (RT5) in the defective state based on load information indicating whether the load (4) is a capacitive load or a resistive load. The first path (RT4) is a path through which power is supplied from the power storage device (3) to the load (4) via the third field-effect transistor (SW3) and the second field-effect transistor (SW2). The second path (RT5) is a path through which power is supplied from the power storage device (3) to the load (4) via a bypass field-effect transistor. The bypass field-effect transistor has a first end connected to the second connection terminal (T2) and a second end connected to a terminal of the third field-effect transistor (SW3) proximal to the second field-effect transistor (SW2).

According to this aspect, the inrush current is prevented by supplying power to the load (4) via the first path (RT4), and the loss caused by the path resistance is reduced by supplying power to the load (4) via the second path (RT5).

A program according to an eighteenth aspect is a program for causing a computer system to execute the method for the controlling backup power supply system (1) according to the sixteenth or seventeenth aspect.

According to this aspect, a decrease in the voltage supplied to the load (4) in a case where the supply of backup power is performed can be prevented.

Not being limited to the above-described aspects, the various configurations (including modifications) of the backup power supply system (1) according to Embodiment 1 or 2 can be implemented by the method for controlling the backup power supply system (1), a (computer) program, or a non-transitory recording medium in which the program is recorded.

The configurations according to the second to eighth aspects are not essential for the backup power supply system (1), and may be omitted appropriately.

### REFERENCE MARKS IN THE DRAWINGS

1 backup power supply system
2 main power supply
3 power storage device
3A first power storage device
3B second power storage device
4 load
9 movable object
10 controller
20 driver circuit
21 first drive circuit
22 second drive circuit
23 third drive circuit
30 switching circuit
91 main movable body
D2, D3 body diode
DT1 masking period
P1 connection point
R1 current detection resistor
RT1 charging path
RT2 backup path
S1 current command value
S2 On-signal
S3 Off-signal
SW1 first field-effect transistor
SW2 second field-effect transistor
SW3 third field-effect transistor
SW4 fourth field-effect transistor
SW10 bypass field-effect transistor
SW11 first bypass field-effect transistor
SW12 second bypass field-effect transistor
T1 first connection terminal
T2 second connection terminal

1. A backup power supply system comprising:
a first connection terminal configured to be connected to a main power supply;
a second connection terminal configured to be connected to a load;
a first field-effect transistor connected between the first connection terminal and the second connection terminal;
a series circuit of a second field-effect transistor and a third field-effect transistor, the series circuit being connected between a power storage device and a connection point of the first field-effect transistor and the second connection terminal; and
a controller, wherein
a body diode included in the second field-effect transistor is connected in a direction allowing a current to flow from the connection point to the power storage device,
a body diode included in the third field-effect transistor is connected in a direction allowing a current to flow from the power storage device to the connection point,
in a non-defective state in which the main power supply is not defective, the controller is configured to turn on the first field-effect transistor and cause the third field-effect transistor to operate in an active region so as to cause a charging current flowing to the power storage device, thereby charging the power storage device via a charging path from the main power supply through the first field-effect transistor, the second field-effect transistor, and the third field-effect transistor, and
in a defective state in which the main power supply is defective, the controller is configured to turn off the first field-effect transistor and turn on the second field-effect transistor and the third field-effect transistor, thereby supplying power from the power storage device to the load.

2. The backup power supply system according to claim 1, wherein
the controller is configured to turn on first field-effect transistor and turn off the second field-effect transistor and the third field-effect transistor when the defective state occurs, and
the controller is configured to turn off the first field-effect transistor and turn on the second field-effect transistor and the third field-effect transistor when the defective state continues for a predetermined masking period.

3. The backup power supply system according to claim 1, wherein
in the non-defective state, the controller is configured to perform a current control by causing the third field-effect transistor to operate in a saturation region or an active region so as to cause the charging voltage of the power storage device to reach the target voltage value in a first period until a charging voltage of the power storage device reaches a target voltage value, and
in the non-defective state, the controller is configured to perform a voltage control by causing the third field-effect transistor to operate in the active region so as to maintain the charging voltage of the power storage device at the target voltage value in a second period after the first period.

4. The backup power supply system according to claim 1, further comprising
a driver circuit configured to drive the third field-effect transistor, wherein
the driver circuit includes:
a first drive circuit configured to cause the third field-effect transistor to operate in the active region based on a current command value input from the controller and a voltage across a current detection resistor connected between the connection point and the power storage device;
a second drive circuit configured to turn on the third field-effect transistor based on an On-signal input from the controller; and
a third drive circuit configured to turn off the third field-effect transistor based on an Off-signal input from the controller.

5. The backup power supply system according to claim 1, further comprising
a bypass field-effect transistor having a first end connected to the second connection terminal and a second end connected to a terminal of the third field-effect transistor proximal to the second field-effect transistor, wherein
in a case where power is supplied from the power storage device to the load in the defective state, the controller is configured to turn on the bypass field-effect transistor.

6. The backup power supply system according to claim 5, wherein
the controller is configured to switch a feeding path to the load to either a first path or a second path in the defective state based on load information indicating whether the load is a capacitive load or a resistive load,
the first path is a path through which power is supplied from the power storage device to the load via the third field-effect transistor and the second field-effect transistor, and
the second path is a path through which power is supplied from the power storage device to the load via the bypass field-effect transistor.

7. The backup power supply system according to claim 6, wherein
in a case where the load is a capacitive load, the controller is configured to switch the feeding path to the first path from an occurrence of the defective state until a switching condition is satisfied, and switches the feeding path to the second path when the switching condition is satisfied.

8. The backup power supply system according to claim 7, wherein the switching condition includes at least one of a condition that a certain period elapses from the occurrence of the defective state, a condition that a discharging current from the power storage device is equal to or lower than a threshold current, a condition that a charging voltage of the power storage device is equal to or lower than a threshold voltage, and a condition that a state of charge of the power storage device is equal to or lower than a threshold.

9. The backup power supply system according to claim 1, further comprising:
a second power storage device different from a first power storage device which is the power storage device;
a fourth field-effect transistor connected between the second power storage device and a terminal of the second field-effect transistor proximal to the third field-effect transistor; and
a switching circuit, wherein
in a case where the second power storage device is charged in the non-defective state, the controller is configured to cause the fourth field-effect transistor to operate in an active region so as to control a charging current flowing to the second power storage device,
in a case where power is supplied from the second power storage device to the load in the defective state, the controller is configured to turn on the fourth field-effect transistor,
the switching circuit is configured to be switched between a first state and a second state in response to a switching signal from the controller,
the first state is a state in which a series circuit of the third field-effect transistor and the first power storage device is connected in parallel to a series circuit of the fourth field-effect transistor and the second power storage device between the second field-effect transistor and a reference potential,
the second state is a state in which the first power storage device is connected in series to the second power storage device between the second field-effect transistor and the reference potential via a parallel circuit of the third field-effect transistor and the fourth field-effect transistor,
in a case where the first power storage device and the second power storage device are charged in the non-defective state, the switching circuit is configured to be switched to the first state in response to the switching signal, and
in a case where power is supplied from the first power storage device and the second power storage device to the load in the defective state, the switching circuit is configured to be switched to the second state in response to the switching signal.

10. The backup power supply system according to claim 9, wherein
in a case where the first power storage device and the second power storage device are charged in the non-defective state, the controller is configured to output the switching signal switching for the switching circuit to the second state, and charge the first power storage device and the second power storage device in the second state, and
when charging voltages of the first power storage device and the second power storage device connected in series to each other reach a predetermined switching voltage value, the controller is configured to output the switching signal for switching the switching circuit to the first state, and charge the first power storage device and the second power storage device in the first state.

11. The backup power supply system according to claim 9, further comprising:
a first bypass field-effect transistor having a first end connected to the second connection terminal and a second end connected to a terminal of the third field-effect transistor proximal to the second field-effect transistor; and
a second bypass field-effect transistor having a first end connected to the second connection terminal and a second end connected to a terminal of the fourth field-effect transistor proximal to the second field-effect transistor, wherein
in a case where power is supplied from the first power storage device and the second power storage device to the load in the defective state, the controller is configured to turn on the first bypass field-effect transistor and the second bypass field-effect transistor.

12. The backup power supply system according to claim 11, wherein
the controller is configured to switch a feeding path to the load to either a first path or a second path in the defective state based on load information indicating whether the load is a capacitive load or a resistive load,
the first path is a path through which power is supplied from the first power storage device and the second power storage device connected in series to each other to the load via the third field-effect transistor, the fourth field-effect transistor, and the second field-effect transistor, and
the second path is a path through which power is supplied from the first power storage device and the second power storage device connected in series to the load via at least one of:
a series circuit of the first bypass field-effect transistor and the third field-effect transistor; and
a series circuit of the second bypass field-effect transistor and the fourth field-effect transistor.

13. The backup power supply system according to claim 12, wherein, in a case where the load is a capacitive load, the controller is configured to:
switch the feeding path to the first path from an occurrence of the defective state until a switching condition is satisfied; and
switch the feeding path to the second path when the switching condition is satisfied.

14. The backup power supply system according to claim 13, wherein the switching condition includes at least one of a condition that a certain period elapses from the occurrence of the defective state, a condition that discharging currents from the first power storage device and the second power storage device are equal to or lower than a threshold current, a condition that a sum of charging voltages of the first power storage device and the second power storage device is equal to or lower than a threshold voltage, and a condition that a state of charge of the first power storage device and the second power storage device is equal to or lower than a threshold value.

15. A movable object comprising:
the backup power supply system according to claim 1; and
a main movable body having the backup power supply system, the main power supply, and the load mounted thereon.

16. A method for controlling a backup power supply system which includes a first connection terminal connected to a main power supply, a second connection terminal connected to a load, a first field-effect transistor connected between the first connection terminal and the second connection terminal, and a series circuit of a second field-effect transistor and a third field-effect transistor, the series circuit being connected between a power storage device and a connection point of the first field-effect transistor and the second connection terminal, wherein a body diode included in the second field-effect transistor is connected in a direction allowing a current to flow from the connection point to the power storage device, and a body diode included in the third field-effect transistor is connected in a direction allowing a current to flow from the power storage device to the connection point, the method comprising:
a charging step of, in a non-defective state in which the main power supply is not defective, charging the power storage device from the main power supply via a charging path through the first field-effect transistor, the second field-effect transistor, and the third field-effect transistor by turning on the first field-effect transistor and by causing the third field-effect transistor to operate in an active region so as to control a charging current flowing to the power storage device; and
a backup feeding step of, in a defective state in which the main power supply is defective, supplying power from the power storage device to the load by turning off the first field-effect transistor and turning on the second field-effect transistor and the third field-effect transistor.

17. The method according to claim 16, further comprising
a switching step of switching a feeding path to the load to either a first path or a second path in the defective state based on load information indicating whether the load is a capacitive load or a resistive load, wherein
the first path is a path through which power is supplied from the power storage device to the load via the third field-effect transistor and the second field-effect transistor,
the second path is a path through which power is supplied from the power storage device to the load via a bypass field-effect transistor, and
the bypass field-effect transistor has a first end connected to the second connection terminal and a second end connected to a terminal of the third field-effect transistor proximal to the second field-effect transistor.

18. A program for causing a computer system to execute the method controlling the backup power supply system according to claim 16.
